(19) United States
(12) Patent Application Publication
(10) Pub. No.: US 2024/0192004 A1
(43) Pub. Date: Jun. 13, 2024

(54) FLEET ROUTE PHYSICS-BASED MODELING

(71) Applicant: Dana Heavy Vehicle Systems Group, LLC, Maumee, OH (US)

(72) Inventors: Abraham MEZAAEL, Southfield, MI (US); Theyaa MATTI, Maumee, OH (US)

(21) Appl. No.: 18/537,505

(22) Filed: Dec. 12, 2023

Related U.S. Application Data
(60) Provisional application No. 63/387,036, filed on Dec. 12, 2022.

(51) Int. Cl. G01C 21/34; G06F 30/15; G06Q 10/0631

(52) U.S. Cl. CPC G01C 21/3469; G01C 21/3461; G01C 21/3492; G06F 30/15; G06Q 10/06311; B60L 53/62

(57) ABSTRACT

Methods and systems are disclosed for operating a fleet of vehicles having a central recharging location. In one example, the method comprises operating at least a first vehicle of the fleet and a second vehicle of the fleet in response to a completion rate being greater than a confidence threshold, where each of the first vehicle and the second vehicle only externally recharge at the central recharging location without external recharging on the respective route of each of the first vehicle and the second vehicle and in response to the completion rate being greater than a confidence threshold, selecting one of the first vehicle and the second vehicle to send on one route of the plurality of routes based on a highest completion rate and sending the unselected vehicle on another route of the plurality of routes based on a next highest completion rate.

### CROSS REFERENCE TO RELATED APPLICATION

The present application claims priority to U.S. Provisional Application No. 63/387,036, entitled “FLEET ROUTE PHYSICS-BASED MODELING”, and filed on Dec. 12, 2022. The entire contents of the above-listed application are hereby incorporated by reference for all purposes.

### TECHNICAL FIELD

The present disclosure relates generally to systems and methods for predicting operation of vehicles parameters with machine learning (ML).

### BACKGROUND AND SUMMARY

Transitioning to fleets that comprise Battery Electric Vehicle (BEV) trucks is hindered by a fleet manager's ability to determine whether a BEV truck is able to finish a route. In particular, the fleet manager's lack of knowledge regarding energy requirements, stops, state of charge of a battery/fuel cell, payload strategy, and other fleet metrics may hinder the decision making ability of the fleet manager. Having access to the aforementioned information may allow the fleet manager to incorporate BEV trucks and appropriately allocate BEV trucks for specific routes. Additionally, the BEV trucks vary in their physical characteristics, such as age, load, and the like, which may affect the ability of a BEV truck to finish a route without having to recharge the battery/fuel cell.

U.S. Pat. No. 10,759,298 B2 to Wang et. al. discloses a system and method for artificial intelligence based predictive charge planning and powertrain control of electric drive vehicles. Machine Learning (ML) models for various vehicle subsystems are used to predict operation of an electric vehicle (EV) and determine state of charge (SOC) of a battery. The ML models rely on data from existing road segments included in OpenStreetMap and other mapping databases to determine road level data as well as traffic conditions and disturbance data. Various vehicle parameters are calculated for each road segment and used to train a driver model to determine maximum (and minimum) acceleration and deceleration rates. Accordingly, in response to the predicted operation of the EV, operation controls are implemented, such as displaying alternate routes, disabling some vehicle systems to conserve battery level, and the like.

The disclosure discussed above relies on existing road segments included in OpenStreetMap and other mapping databases to obtain road level data and calculate vehicle parameters used to train a driver model. While such an approach may reduce computational load of the system, the accuracy of the driver model as well as other vehicle subsystem models may be reduced for fleets that include BEV trucks. In particular, when compared to operation of other BEV vehicles, operation of BEV trucks may be more significantly affected by route parameters, such as traffic conditions, weather conditions, wind conditions, and the like. As such, a simplified approach that does not consider the effects of the aforementioned route parameters and effects of variable route parameters of different segments on the vehicle subsystems may result in inaccurate predictions when assigning routes to real vehicles based on the simulation results.

The inventors hereby recognize the disadvantages with current systems and attempt to address the disadvantages by operating a fleet of vehicles having a central recharging location based on results from a physics-based simulation system that relies on a segmentation model to segment the route. More specifically, the disadvantages may be addressed with a method that includes operating at least a first vehicle of the fleet and a second vehicle of the fleet with different physical characteristics in response to a completion rate being greater than a confidence threshold, where each of the first vehicle and the second vehicle only externally recharge at the central recharging location without external recharging on the respective route of each of the first vehicle and the second vehicle and where the completion rate is generated by, for each of the first vehicle and second vehicle, entering the route of a plurality of routes via a fleet management system (FMS) communicatively coupled to a physics-based simulation system, validating each route via the physics-based simulation system, the physics-based simulation system comprising a vehicle model that simulates operation of a virtual vehicle and a segmentation model, storing collected simulation data in a data lake, and generating a statistical summary report based on simulation data stored in the data lake and displaying the statistical summary report to a user, in response to the completion rate being greater than a confidence threshold, selecting one of the first vehicle and the second vehicle to send on one route of the plurality of routes based on a highest completion rate and sending the unselected vehicle on another route of the plurality of routes based on a next highest completion rate, and in response to a route not being matched to either of the first vehicle and the second vehicle due to a completion rate not being greater than the confidence threshold, sending a hybrid vehicle or internal combustion engine (ICE) vehicle on the route.

The above advantages and other advantages, and features of the present description will be readily apparent from the following Detailed Description when taken alone or in connection with the accompanying drawings. It should be understood that the summary above is provided to introduce in simplified form a selection of concepts that are further described in the detailed description. It is not meant to identify key or essential features of the subject matter. Furthermore, the subject matter is not limited to implementations that solve any disadvantages noted above or in any part of this disclosure.

### BRIEF DESCRIPTION OF THE DRAWINGS

The disclosure may be better understood from reading the following description of non-limiting embodiments, with reference to the attached drawings, wherein below:

FIG. 1 illustrates a schematic illustration of a fleet route physic-based modeling system;

FIG. 2 illustrates a schematic illustration of physics-based simulation system;

FIG. 3 schematically illustrates an example process for determining a completion rate of a BEV to finish a route based on one or more potential routes;

FIG. 4 schematically illustrates an example process for serially determining state of charge of a BEV;

FIG. 5A is a schematic representation of a first portion of a model of a vehicle, in accordance with one or more embodiments of the present disclosure;

FIG. 5B is a schematic representation of a second portion of a model of a vehicle, in accordance with one or more embodiments of the present disclosure;

FIG. 5C is a schematic representation of components of a cloud ecosystem interacting with a model of a vehicle, in accordance with one or more embodiments of the present disclosure;

FIG. 6 schematically illustrates an example process for training a segmentation model based on route parameters of a potential route;

FIG. 7 schematically illustrates an example process for training a vehicle model based on a plurality of segments of a potential route;

FIG. 8 illustrates a flow diagram of a method for generating a completion rate of a BEV vehicle based on fleet route physics-based modeling;

FIG. 9 illustrates a flow diagram of a method for validating the route with a simulation engine; and

FIG. 10 illustrates a timing sequence for fleet route physics-based modeling; and

FIG. 11 illustrates a flow diagram of a method for selecting vehicles from a fleet of vehicles to send on a route.

### DETAILED DESCRIPTION

The methods and systems described herein relate to operating a fleet of vehicles based on results from a physics-based simulation system that simulates operation of a battery electric vehicle (BEV), and more specifically BEV trucks of a fleet to predict a completion rate based on a predicted battery voltage (or state of charge (SOC)). Each vehicle in the fleet of vehicles may be selected for a route of a plurality of routes. For each route, the physics-based simulation system determines one or more potential routes for the respective route wherein each of the potential routes includes variable route parameters or route characteristics at different points of the respective potential route. Accordingly, operation of a BEV vehicle may differ based on the variable route parameters encountered when operating the BEV vehicle. To account for these differences in vehicle operation when simulating each potential route, each potential route and the route parameters associated with the respective potential route may be entered as input to a segmentation model, which may be a machine learning (ML) model, that generates a plurality of segments for each potential route. The segmentation model may segment each potential route based on uniformity of the route parameters at various points along the potential route. In this way, the plurality of segments may be serially entered in a pre-determined order to a vehicle model that simulates various vehicle subsystems of a real BEV vehicle to predict a battery voltage (e.g., SOC) and other vehicle operation parameters to predict a completion rate for the route. Each vehicle of the fleet of vehicles may be sent on one route of the pluralities of routes based on the completion rate being greater than a confidence threshold (e.g., a pre-determined completion rate), where a vehicle with a highest completion rate for a particular route is sent on that particular route.

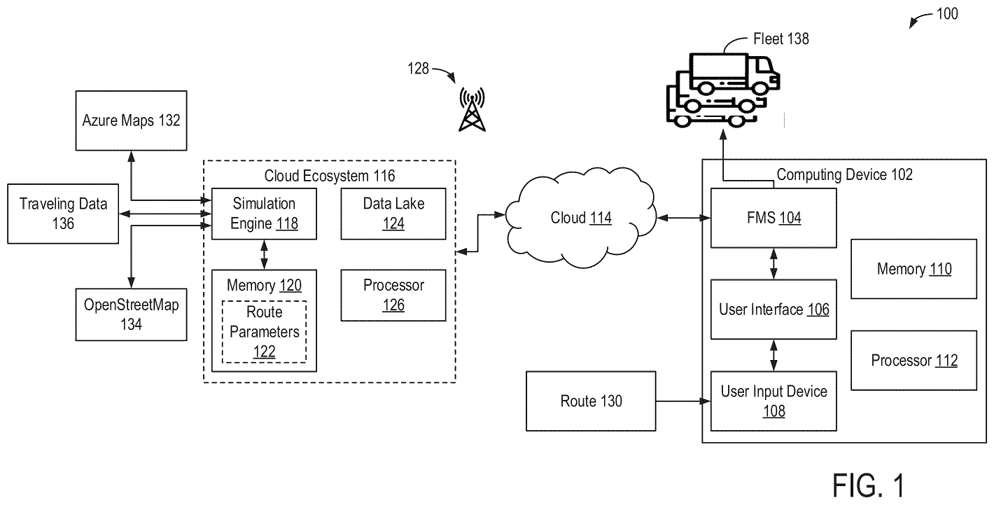

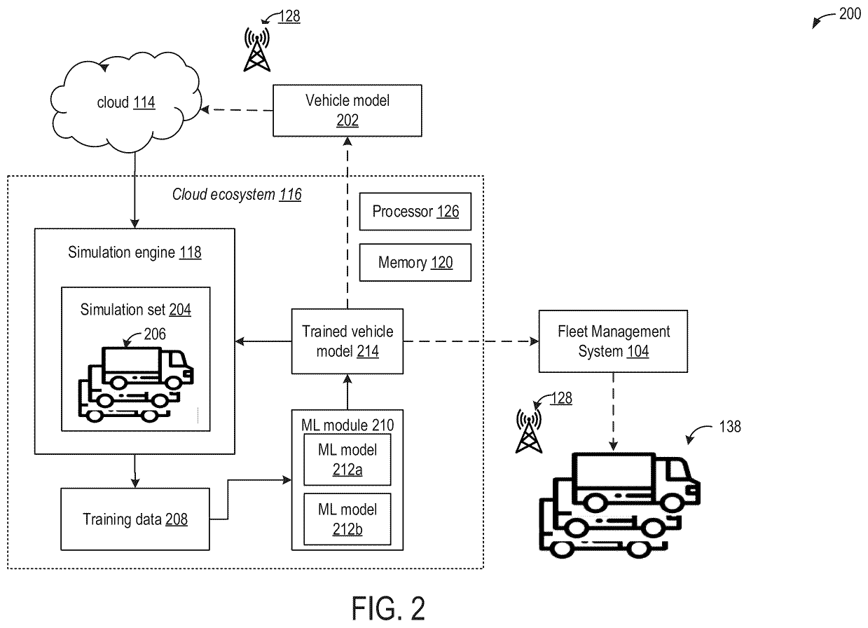

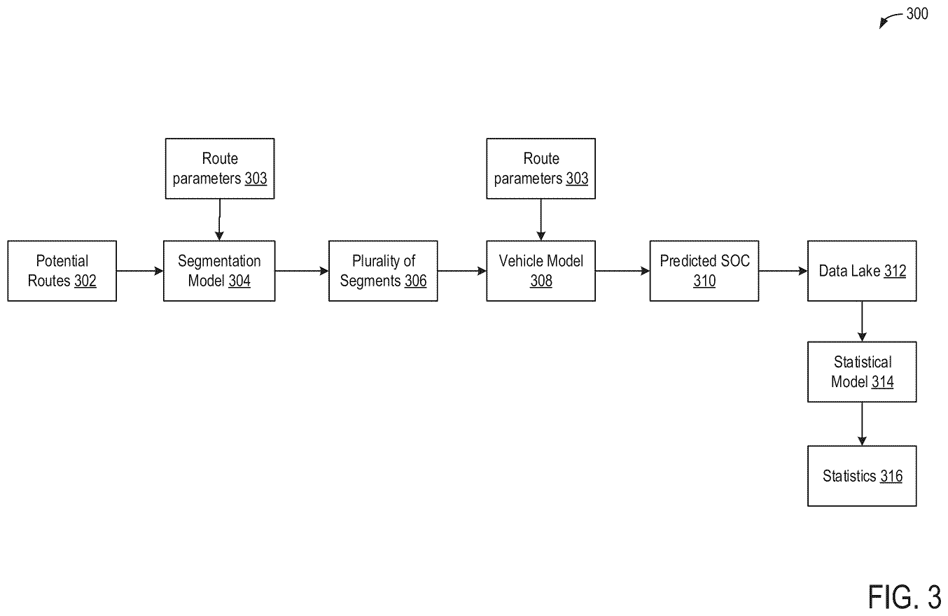

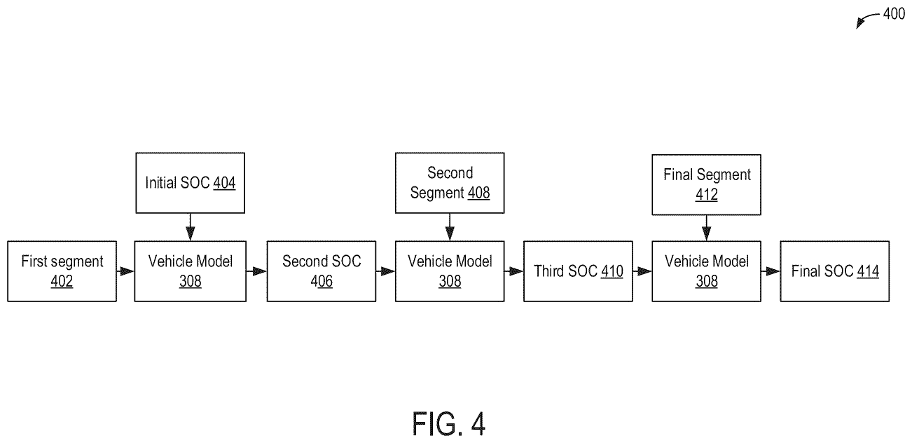

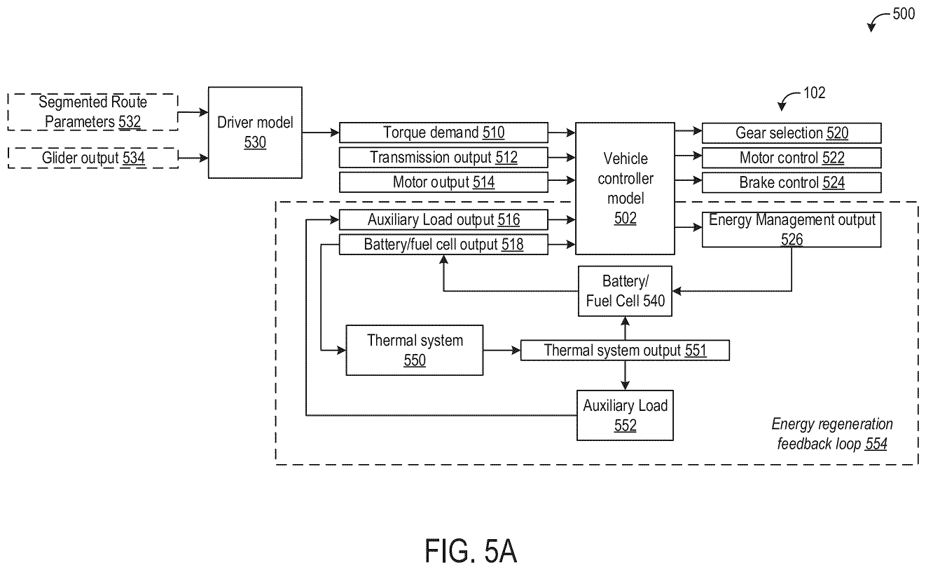

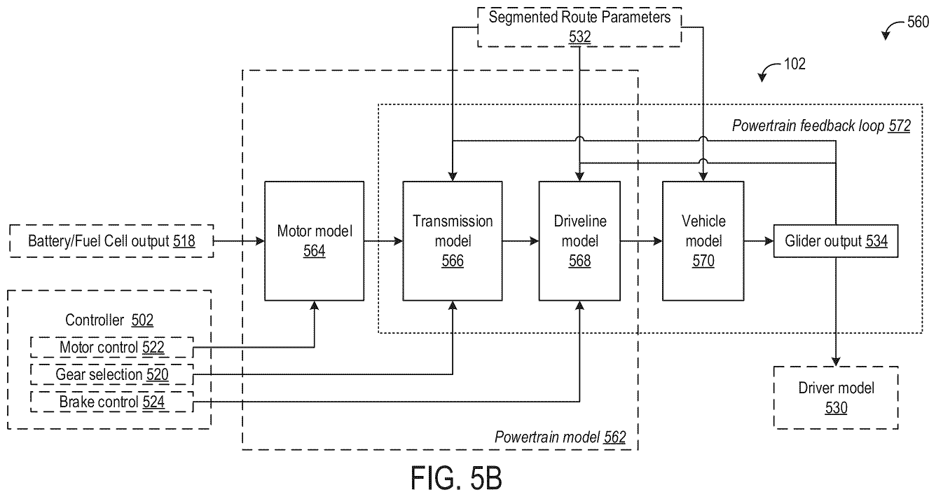

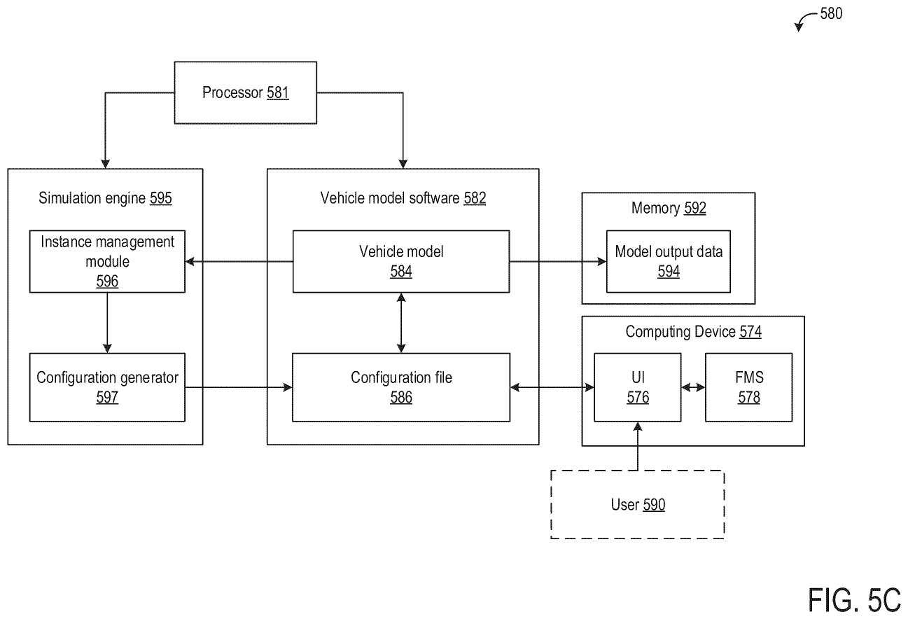

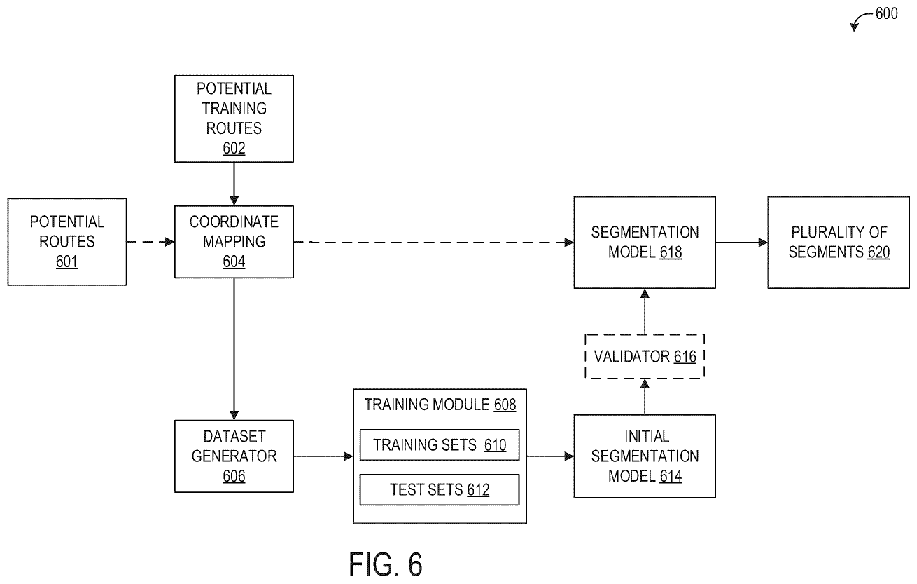

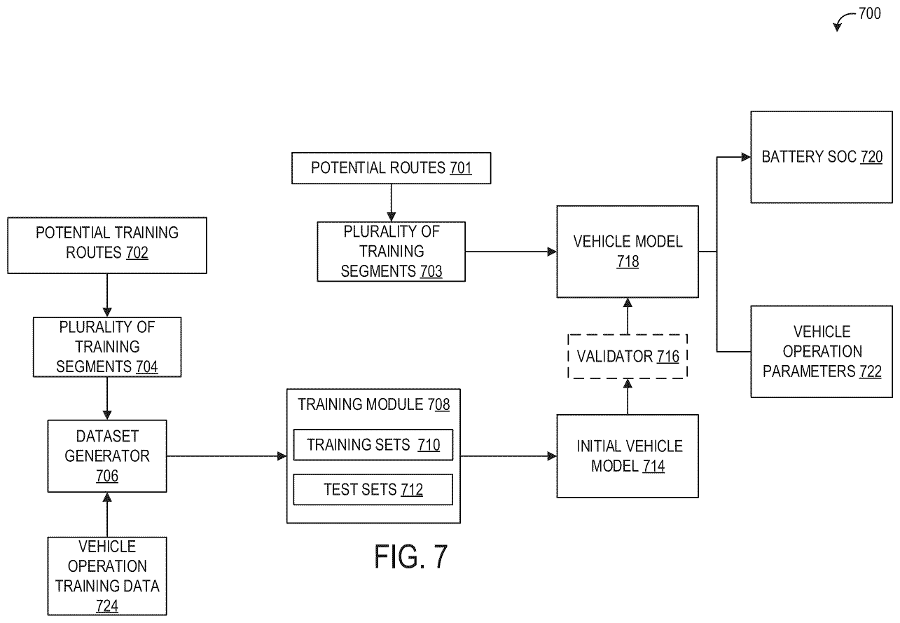

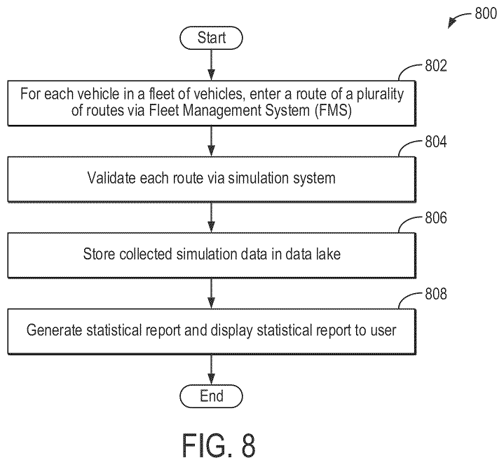

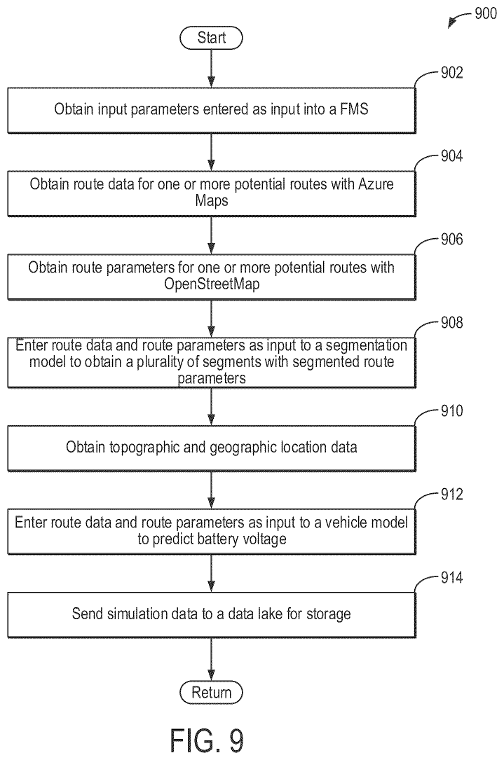

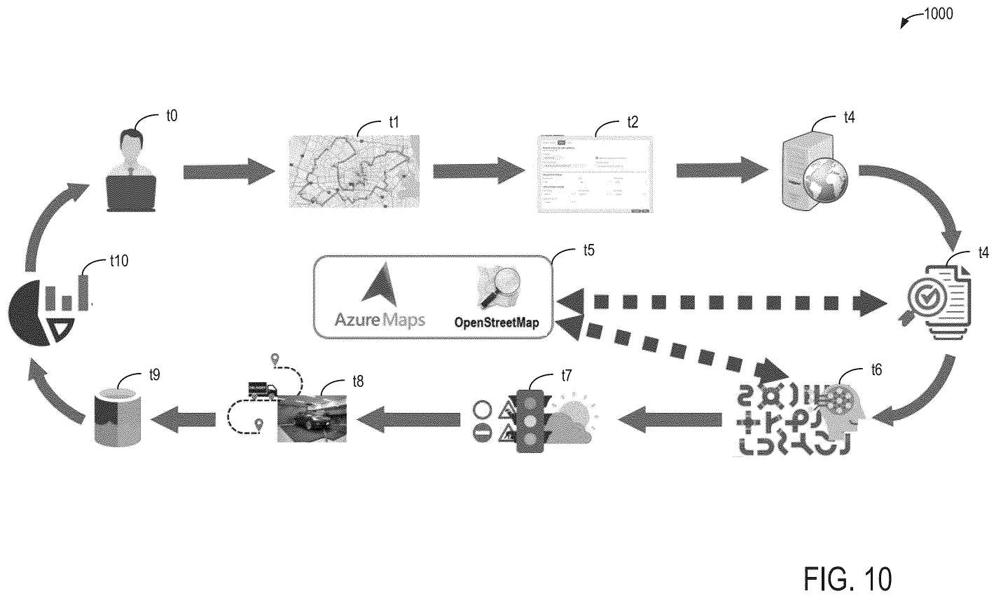

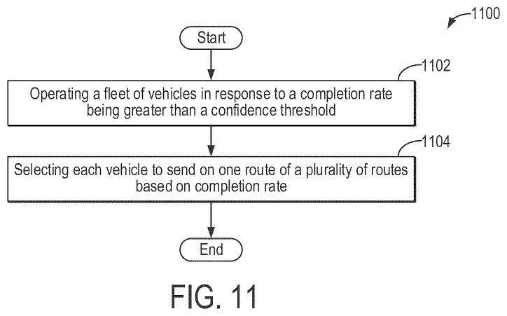

The system and components of the fleet route physics-based modeling system are shown in FIG. 1. FIG. 2 illustrates the system and components of a physics-based simulation system. FIG. 3 illustrates an example process for predicting a completion rate with the physics-based simulation system. An example process for serially entering each segment of a plurality of segments as input to a vehicle model when simulating operation of a virtual vehicle is illustrated in FIG. 4. A first portion of the vehicle model including a driver model and a vehicle controller model is shown in FIG. 5A, and a second portion of the vehicle model including a powertrain model and a vehicle model is shown in FIG. 5B. The vehicle model may be bundled in software that supports flexible configuration for parallelized simulation, as shown in FIG. 5C. An example process for training a segmentation model is shown in FIG. 6 and an example process for training a vehicle model is shown in FIG. 7. A method for predicting a completion rate for a BEV vehicle using the fleet route physics-based modeling system is shown in FIG. 8. As shown in FIG. 9, a method for performing a simulation with the simulation system. FIG. 10 shows a timing sequence of an example implementation of the fleet route physics-based modeling system. FIG. 11 illustrates a method for operating a fleet of vehicles based on simulation results in accordance with the embodiments described herein.

FIG. 1 illustrates a fleet route physics-based modeling system 100 utilized to determine whether a battery electric vehicle (BEV) vehicle, such as a BEV truck of a fleet, may successfully finish a route, the route beginning at an initial location and ending at a final destination. In some embodiments wherein a central recharging location is located at the initial location, the initial location may be the same as the final destination. The central recharging location does not include recharging by regenerative braking events, solar panels, and a high speed charging at an external recharging location, the external recharging location being different than the central recharging location, and the like. In this way, recharging occurs via a slow, controlled charge instead of a fast speed charge in the field. In particular, the fleet route physics-based modeling system 100 may include an electronic device wherein a management system is configured, stored, and executed in memory by at least one processor of the electronic device. Accordingly, the management system may evaluate a completion rate of the route based on statistics generated from output received from a simulation system in a cloud ecosystem. In this way, a virtual vehicle traveling along one or more potential routes may be simulated with a vehicle model.

The one or more potential routes may have the same initial location, the same final destination, and a same number of stops. The location of each stop may be the same for all of the potential routes. In some embodiments, the one or more potential routes but may differ in regards to the directions and roads traveled to reach the final destination. In other embodiments, a subset of the one or more potential routes may have the same directions and may travel on the same roads to reach the final destination, such as when modeling different vehicles of a fleet, where each vehicle has different physical characteristics, such as age, tire wear, load, and the like. Additionally, simulation of the subset of the one or more potential routes may occur under different driving conditions. Output from the vehicle model for each of the potential routes may be subjected to statistical analysis to predict the completion rate of the virtual vehicle for different vehicles of a fleet. The completion rate indicates the likelihood or percentage that the vehicle successfully finishes the potential route without exceeding an accepted battery discharge level and/or without undesired detours or stops to charge the battery. The route may be recommended and/or selected from the one or more potential routes based on the completion rate.

The fleet route physics-based modeling system 100 may include a computing device 102, a cloud 114, and a cloud ecosystem 116. The computing device 102 may comprise a fleet management system (FMS) 104, a user interface 106, a user input device 108, a memory 110, and a processor 112. The FMS 104 may be communicatively coupled to the user interface via the user input device 108. Further, the FMS 104 may be communicatively coupled to the cloud ecosystem 116 via the cloud 114. Instructions configured, stored, and executed in memory 110 by the processor 112 may enable information to be transmitted from the FMS 104 to the cloud ecosystem 116 via the cloud 114 over a network 128, and vice versa. The network 128 may be a suitable wired or wireless network (e.g., the Internet). In various embodiments, network 128 may include a wireless cellular network to which FMS 104 is connected. In this way. the route 130 with driving condition preferences (e.g., selectable input parameters) may be entered as input into and validated by the FMS 104 and evaluated by a simulation system in the cloud ecosystem 116.

The user interface 106 may comprise a display device and a user input device 108. The display device may include one or more display devices utilizing any type of display technology. In some embodiments, the display device may comprise a computer monitor and may display a graphical representation of the route, selectable input parameters of a plurality of input parameters, and fleet route modeling summary, for example. The display device may be combined with the processor 112, the memory 110, and/or the user input device 108 in a shared enclosure or may be a peripheral display device. The display device may include a monitor, a touchscreen, a projector, or another type of display device, which may enable a user to interact with various data stored in the memory 110. In some embodiments, the display device may be included in a smartphone, a tablet, a smartwatch, or the like.

The user input device 108 may comprise one or more of a touchscreen, a keyboard, a mouse, a trackpad, a motion sensing camera, or other device configured to enable a user to interact with and manipulate data stored within the FMS 104. In some embodiments, such as touchscreen embodiments, the user input device 108 is integrated with the display device. In particular, the route 130 and preferred driving conditions (selectable input parameters) may be entered as input into the FMS 104 via the user interface 106 via user input device 108. The preferred driving conditions may include a number of stops, desired weather conditions, desired traffic conditions, and the like.

As discussed herein, a plurality of memories, such as memory 110, of the fleet route physics-based modeling system may include a non-transitory computer readable medium in which instructions are stored. For the purposes of this disclosure, the term “non-transitory computer readable medium” is expressly defined to include various types of computer readable storage, which in various embodiments may include a non-transitory computer readable medium such as a flash memory, a read only memory (ROM), a random access memory (RAM), a cache, or any other storage media (e.g., a tangible medium) in which information is stored for any duration (e.g., for extended period time periods, permanently, brief instances, for temporarily buffering, and/or for caching of the information). Computer memory of computer readable storage mediums as referenced herein may include volatile and non-volatile or removable and non-removable media for a storage of electronic-formatted information such as computer readable program instructions or modules of computer readable program instructions, data, and the like that may be stand-alone or as part of a computing device. Examples of computer memory may include any other medium which can be used to store the desired electronic format of information and which can be accessed by the processor or processors or at least a portion of a computing device. Various methods and systems disclosed herein may be implemented using instructions (e.g., programming instructions, coded instructions, executable instructions, computer readable instructions, and the like) stored in a non-transitory computer readable medium.

The cloud ecosystem 116 may comprise a simulation engine 118, a memory 120, a data lake 124, and a processor 126. The simulation engine 118 may generate a virtual vehicle based on a physics-based vehicle model of a real vehicle via instructions stored and executed in memory 120 by processor 126. Operation of the virtual vehicle may be simulated by the simulation engine 118, under various conditions and scenarios, with performance data being collected. In particular, the simulation engine 118 may run simulations wherein the virtual vehicle travels on the one or more potential routes and each potential route includes one or more of route parameters 122. The route parameters 122 may be historical and/or real time driving conditions or preferred driving conditions entered into the FMS 104 via a user input device 108 and transmitted to the memory 120 via the cloud 114 over network 128. Some examples of the route parameters 122 may include preferred weather forecasts, road conditions, traffic conditions, and the like.

The simulation engine 118 may access data via the network 128, including Azure Maps 132, OpenStreetMap 134, and traveling data 136. As such, the simulation engine 118 may validate the one or more potential routes via Azure Maps 132, and segment the one or more potential routes based on segment characteristics and data collected from OpenStreetMap 134 via machine learning (ML). By accessing traveling data 136, the simulation engine 118 may obtain historical traveling data and real-time or near real-time traveling data, such as weather forecasts, road conditions, traffic conditions, and the like for the potential routes and/or segments of the route. In some embodiments, traveling data may be obtained from Azure Maps. In other embodiments, traveling data may be obtained from databases accessed through the wired or wireless networks (e.g., the Internet). After running the simulation, the simulation engine 118 may store simulation data in the data lake 124, perform a statistical analysis on the simulation data, generate a statistical summary report based on the simulation data and statistical analysis, and output the statistical summary report to the FMS 104 via the cloud 114 via network 128 via instructions stored and executed in memory 120 by processor 126. A fleet manager may review the statistical summary report and decide whether the virtual vehicle in the fleet 138 may successfully finish the route according to a method described below in FIG. 11.

Referring now to FIG. 2, a physics-based simulation system 200 is shown for simulating operation of a plurality of virtual vehicle, such as a virtual battery electric vehicle (BEV), based on the operation of a real BEV. In some embodiments, the virtual vehicle may be trained via a first machine learning (ML) model with data collected from a plurality of real vehicles or the plurality of virtual vehicles to increase the accuracy of predictions for a completion rate of the route for a real BEV. Specifically, the first ML model may be trained to output a set of parameters of one or more vehicle systems of the real vehicle, including a voltage related to state of charge (SOC) of a battery/fuel cell, as one example. In this way, the first ML model may simulate a vehicle (e.g. virtual vehicle) traveling on one or more potential routes. A second ML model may be trained to output a plurality of segments for each potential route. In this way, the plurality of segmented may be entered as input to the first ML model that simulates operation of a virtual vehicle along one or more potential routes.

The physics-based simulation system 200 may include a vehicle model 202 of the vehicle of a fleet 138 of vehicles. For example, fleet 138 may be a fleet of delivery trucks for a commercial distributor. The vehicle is a real-world, physical vehicle and thus may include vehicle systems and components, which may include but is not limited to a motor, a battery/fuel cell, a transmission, a suspension system, a brake system, a vehicle heating, ventilation, and cooling (HVAC) system, cabin accessories (e.g., in-vehicle entertainment system), and a vehicle control unit (VCU). The VCU may store in memory various calibratable vehicle parameters, which may include motor parameters (e.g., motor torque as a function of accelerator pedal position), transmission parameters, battery parameters, auxiliary load parameters, and the like.

Vehicle model 202 may model various elements and/or subsystems of the vehicle, such as a controller, a powertrain, physical characteristics of the vehicle, and the like. Thus, the virtual vehicle may be referred to as a training vehicle. In various embodiments, the vehicle model may be a computer model of a software program comprising various subsystem models, each subsystem model receiving one or more inputs and generating one or more outputs that may be inputted back into one or more of the subsystem models. In other words, vehicle model 202 may comprise various feedback loops between internal components, whereby an initial set of parameters (e.g., driver data, route data, weather data, vehicle data) may be inputted into vehicle model 202 and simulated operational (e.g., vehicle performance) data of the virtual vehicle may be generated and collected based on the initial set of parameters over a drive cycle (e.g., state of charge of a battery/fuel cell). In various embodiments, vehicle model 202 may be created based on historical and/or statistical information collected from a plurality of vehicles of fleet 138. Vehicle model 202 may be built based on sensor and controller data collected from the vehicle, including vehicle sensor data obtained from sensors installed on the vehicle (and that may be installed on one or more vehicles of fleet 138) and instrumentation sensor data obtained from non-vehicle sensors (e.g., from a dynamometer on which the vehicle is operated) and/or sensors that are specifically installed on the vehicle for the purposes of model generation (and hence are not installed on any vehicles of fleet 138).

Physics-based simulation system 200 may include the cloud 114 and vehicle model 202 may be uploaded to the cloud ecosystem 116 of cloud 114 over the network 128. Cloud ecosystem 116 may include a simulation engine 118, training data 208, and an ML module 210 that generates a trained vehicle model 214. The ML module 210 may also generate a trained segmentation model.

Simulation engine 118 may generate a simulation set 204 of a plurality of virtual vehicles 206, where each virtual vehicle is based on vehicle model 202. Simulation set 204 may include tens of thousands of vehicles, or hundreds of thousands of vehicles, or millions of vehicles. In some embodiments, each virtual vehicle of simulation set 204 may include the same or substantially similar parameters, while in other embodiments, each virtual vehicle may include different parameters. For example, each virtual vehicle may be assigned an initial set of parameters of vehicle model 202 that have been adjusted to reflect variability and/or differences (e.g., age, wear, size, weight) between each virtual vehicle of fleet 138.

For example, a first virtual vehicle may be initialized with a set of parameters of vehicle model 202 corresponding to a new truck of a first size; a second virtual vehicle may be initialized with a set of parameters of vehicle model 202 corresponding to a new truck of a second size; a third virtual vehicle may be initialized with a set of parameters of vehicle model 202 corresponding to an older truck of the first size; a fourth virtual vehicle may be initialized with a set of parameters of vehicle model 202 corresponding to an older truck of the second size; and so on. In some examples, when different virtual vehicles are initialized with different sets of parameters, multiple copies/versions of each different virtual vehicle may be generated. For example, multiple copies of the first virtual vehicle may be generated, multiple copies of the second virtual vehicle may be generated, etc. In this way, each copy of the respective virtual vehicle may be used in a different simulation wherein in each simulation, the respective virtual vehicle travels along one potential route of the one or more potential routes.

Each virtual vehicle may also be assigned an initial set of drive cycle parameters defining a drive cycle, driver style, and driving conditions. The driving conditions may include, for example, road conditions, weather conditions, lighting conditions (e.g., a time of day/night), environmental conditions (e.g., heat, cold), and the like. The initial drive cycle parameters may similarly be adjusted to cover a range of different routes and conditions, to ensure that data collected has a desired distribution.

Simulation engine 118 may initiate a virtual vehicle simulation, where an operation of each virtual vehicle of simulation set 204 is simulated individually. In various embodiments, two or more or each of the individual simulations may be performed concurrently. Specifically, simulation engine 118 may be built using software technologies (including open-source software technologies) designed to run in a distributed computing environment, such that simulation of the operation of each virtual vehicle may be carried out in parallel, to facilitate horizontal scaling to a desired size.

During the virtual vehicle simulation, performance and other data of each virtual vehicle may be collected. The operation of each virtual vehicle may be simulated under different conditions, as described above. For example, the plurality of virtual vehicles 206 may operate on different potential routes, at different times of the day, during different seasons and during different environmental and/or climactic conditions, and so on. Further, different driver models may be used to simulate different driving behaviors of different drivers. In addition, a same virtual vehicle may be used to simulate the virtual vehicle traveling on different potential routes, the different potential routes having variable driving conditions. As such, output data pertaining to the respective virtual vehicle, such as a final state of charge (SOC) of the battery/fuel cell, may be obtained after running each simulation. Once a virtual vehicle simulation has been performed on a virtual vehicle, one or more parameters of the virtual vehicle may be adjusted and/or the conditions under which the simulation is carried out may be adjusted, and a new simulation may be performed, such that the virtual vehicle simulations may be carried out in parallel and serially as desired. In other embodiments, the output data collected during the virtual vehicle simulation and stored in a data lake (e.g., data lake 124) for statistical analysis.

In some embodiments, training data 208 may include sensor data and the like as described above. In other embodiments, training data 208 may subsequently be generated from the performance data collected from the virtual vehicle simulation. The performance data may be generated based on sensor data and the like. Relevant performance data may be extracted and codified to create training data 208, for the purposes of training a first ML model 212a and a second ML model 212b of the ML module 210.

Both of the first ML model 212a and the second ML model 212b may include one or more suitable ML model architectures, such as neural networks, random forest, decision trees, Bayesian networks, etc. The second ML model 212b may be trained to segment one or more potential routes based on route parameter uniformity. The first ML model 212a may be trained to generate a variety of desired output based on output from the second ML model 212b. In an example, the first ML model 212a may be trained to mimic performance of the virtual vehicle under any condition, and thus may be trained to output vehicle sensor and controller data that may be observed given a set of route parameters. In this example, once trained (e.g., once the trained vehicle model 214 is generated), the trained ML model may be a super- or meta-model that collapses each virtual vehicle of the simulation set 204 into a single model and thus demand fewer memory and processing resources. The trained vehicle model 214 may then be used to predict vehicle control parameters, such as voltage of a battery/fuel cell, which is related to state of charge (SOC) of a virtual vehicle battery.

Physics-based simulation system 200 may include a fleet management system (FMS) 104. After training of the first ML model 212a has concluded, the trained vehicle model 214 may be used to predict a set of parameters of the specific systems or subsystems. For example, under a first set of driving conditions, where a vehicle is being operated on a first grade, under a first set of weather, road, and temperature conditions, trained vehicle model 214 may output a low state of charge of the virtual vehicle battery, indicating that the virtual vehicle may be charged during the route to successfully finish a first potential route. Under a second set of driving conditions, where a vehicle is being operated on a second grade, under a second set of weather, road, and temperature conditions, trained vehicle model 214 may output a higher state of charge of the virtual vehicle battery, indicating that the virtual vehicle may not be charged during the first potential route to successfully finish the route. Thus, trained vehicle model 214 may be used to predict parameters of the virtual vehicle that determine whether a virtual vehicle battery may be charged during the route to successfully finish the route.

In various embodiments, generating the set of parameters leading to the predicted performance may include generating a new set of output data from trained vehicle model 214 based on a new set of input data. For example, training data 208 may include a first set of inputs relating to vehicle sensor and/or parameter data, and a second set of inputs relating to factors not sensed at the vehicle. The second set of inputs may include route parameter data (e.g., route parameters 122) collected from Azure Maps, OpenStreetMap, or online databases. The factors not sensed at the vehicle may include, for example, a grade on which vehicle operation is simulated, or a simulated road load of the vehicle. In one example, a new set of input data may include the first set of inputs, and may not include the second set of inputs. Trained vehicle model 214 may then be used to output state of charge of the virtual vehicle battery based on vehicle sensor and vehicle parameter data (e.g., the first set of inputs), and not based on factors not sensed at the vehicle (e.g., the second set of inputs). In some embodiments, an expert (e.g., an engineer of the manufacturer) may then analyze the input data and the output data to determine how parameters of the vehicle may be configured to predict state of charge of the virtual vehicle battery in response to different sets of inputs from vehicle sensors.

In some embodiments, analyzing the input data and the output data may include using additional or secondary modeling techniques to model the input data and the output data and/or a performance of trained vehicle model 214. For example, high dimensional statistical methods (e.g., regressions, k-means, etc.) may be used to identify patterns in the input data and the output data. In some embodiments, trained vehicle model 214 may be retrained with the new input data, using reinforcement learning and/or supervised learning with new generated ground truth data.

Additionally, trained vehicle model 214 may be used to update vehicle model 202. In various embodiments, simulation engine 118 may rerun the virtual vehicle simulation with a new simulation set 204 generated from the updated vehicle model 202, to further enhance performance of virtual vehicles 206. In this way, repeated simulations performed by simulation engine 118 may iteratively increase the performance of virtual vehicles 206 and/or virtual vehicles of fleet 138.

Cloud ecosystem 116 may include one or more processor 126, which may be used by simulation engine 118 and/or ML module 210 to process instructions stored in a memory 120. An advantage of running simulation engine 118 and ML module 210 in cloud ecosystem 116 is that a plurality of processors, including processor 126, and an amount of memory 120 may be assigned on demand, based on operational parameters of simulation engine 118 and/or ML module 210. Additionally, a plurality of processors, including processor 126, may execute instructions stored in memory 120 in parallel within a distributed computing environment, which may permit a larger amount of data to be used in simulation and training and result in shorter simulation and training times.

Thus, by collecting performance data from a first plurality of real vehicles and using the performance data to generate a vehicle model of the real vehicles, and subsequently simulating the operation of a plurality of virtual vehicles based on the vehicle model, an amount of performance data of the real vehicles may be increased. The increased amount of performance data may then be used to create and/or train a high dimensional statistical model, such as a first ML model, to output parameter settings that may predict the performance of the real vehicles.

FIG. 3 is a process 300 for determining a completion rate of a virtual vehicle for a route. The route comprises an initial location and a final destination wherein a real vehicle (e.g., BEV truck) may stop at various locations prior to reaching the final destination. A plurality of stops along the route may be determined by a user of a fleet management system (FMS), which may be an embodiment of FMS 104. The route may be one of one or more potential routes, wherein each of the potential routes have the same initial location and final destination. In some embodiments, the initial location and the final destination may be the same. The potential routes may vary with regards to roads traveled on and/or an order wherein the vehicle arrives at each of the plurality of stops.

The process 300 includes determining one or more potential routes by validating the route with Azure Maps. By inputting relevant data into Azure Maps, such as an initial location and the final destination of the route, number of stops, a start time, and the like, Azure Maps may output route data for one or more potential routes. The route data may include directions to each of the stops and the final destination, traffic data, weather data, and the like. The route data may be received from Azure Maps and used as input for a segmentation model 304 or a vehicle model 308 depending on the embodiment.

Each potential route and route parameters 303 associated with the respective potential route may be entered as input into a segmentation model 304 wherein the respective potential route is segmented based on uniformity of the route parameters along the segment. In other words, the route parameters that define the driving conditions of the segment remain the same or nearly the same. The route parameters 303 may be received from Azure Maps, online databases accessed via the Internet, and/or OpenStreetMap. The route parameters 303 may include road grade, sinuosity, traffic conditions, wind conditions, weather conditions, and the like. As an example, the potential route may be segmented based on road grade, sinuosity, speed, traffic conditions, wind conditions, and the like. The segmentation model 304 may be a machine learning (ML) model that identifies portions of the potential route that have similar route parameters. The ML model may include one or more suitable ML model architectures, such as neural networks, random forest, decision trees, Bayesian networks, etc.

As such, the segmentation model 304 may be trained to identify nodes, ways, and/or relations associated with roadways (e.g., highways) in OpenStreetMap that have similar route parameters. A node refers to a single point in space that is demarcated by a longitude, a latitude, and an identification and a way comprises at least two nodes and no more than 2000 nodes. Relations comprise an ordered list of nodes and/or ways and a tag that describes the node and/or way and a value for the node and/or way. Nodes, ways, and relations all have tags. Tags include information regarding a type of roadway, speed limits, grade, sinuosity of the roadway, and the like. The segmentation model 304 may combine relevant nodes and/or ways that define potential routes based on similarities of the route parameters of the nodes and/or ways to generate a segment of the plurality of segments 306. In particular, the segmentation model 304 may utilize the tags associated with the ways to determine similarities between different nodes and/or ways.

The process 300 includes entering relevant route parameters 303 and the plurality of segments 306 individually into a vehicle model 308, which may be an embodiment of vehicle model 202. The vehicle model 308 may comprise a plurality of models for various subsystems of the virtual vehicle. Relevant route parameters may be input to the various subsystems. The vehicle model is described further in FIGS. 5A and 5B. The sequential entering of segments as input into the vehicle model 308 is described below in FIG. 4. For each potential route, the vehicle model 308 may output a predicted state of charge (SOC) 310 of a battery/fuel cell of the virtual vehicle. In addition, the vehicle model 308 may output other vehicle parameters that affect a completion rate of the virtual vehicle. The predicted SOC 310 and other vehicle parameters may be stored in a data lake 312.

After the one or more potential routes 302 have been simulated and the vehicle parameters have been stored in the data lake 312, the vehicle parameters may be entered as input to statistical model 314. The statistical model 314 may output statistics 316 regarding the completion rate of the virtual vehicle. In particular, statistics 316 may include individual completion rates based on state of charge (SOC) of the virtual vehicle for each potential route and an overall completion rate for the one or more potential routes based on SOC of the virtual vehicle after all the one or more potential routes. In other embodiments wherein the simulation includes the same virtual vehicle traveling on the same potential route (e.g., same number of stops, etc.) under different driving conditions, a completion rate based on the different driving conditions may be determined. Further, for virtual vehicles in a fleet traveling on the same potential route, a completion rate may be output for each virtual vehicle. Each of the completion rates discussed above may have a margin of uncertainty. In this way, the potential routes may be selected from the one or more potential routes as well as which vehicles that will be sent on the selected potential routes based on which potential route and vehicle has a highest completion rate.

FIG. 4 is a process 400 for serially entering one segment of a plurality of segments into a vehicle model 308 that simulates a virtual vehicle traveling on a route. The plurality of segments may be output from a segmentation model (e.g., segmentation model 304) that segments one potential route of one or more potential routes at a time. The plurality of segments may include a first segment 402, a second segment 408, and a final segment 412. As described herein, the segmentation model segmented the potential route based on uniformity of the route parameters, which may include road grade, speed limit, length, wind speed, weather conditions, and the like. For example, the first segment 402 may have a road grade of 5%, a speed limit of 60 mph, wind speed of 15 mph, a length of 30 miles, etc., the second segment 408 may have a road grade of 2%, a speed limit of 35 mph, wind speed of 20 mph, a length of 5 miles, etc. and the final segment 412 may have a road grade of −5%, a speed limit of 25 mph, wind speed of 15 mph, and a length of 1 mile, etc. The length of each segments may vary and in some embodiments, the length of the segments may be estimated with algorithms and/or equations depending on a degree of sinuosity and other route parameters of the potential route.

The process 400 includes entering the respective route parameters of the first segment 402 and an initial state of charge (SOC) 404 as input into the vehicle model 308. As described above, the vehicle model 308 includes various subsystems. A first subset of route parameters and their respective values may be entered into a first subsystem wherein the first subset of parameters affect performance of the first subsystem, a second subset of relevant route parameters may be entered into a second subsystem wherein the second subset of parameters affect performance of the second subsystem, and so on. In this way, the subsystems may accurately simulate the performance of the virtual vehicle under those specific driving condition based on the initial SOC 404 and increase the accuracy of the vehicle model 308 to predict a voltage (or state of charge (SOC)) of a battery/fuel cell of the virtual vehicle. In turn, a second SOC 406 may be output from the vehicle model 308.

The process 400 further includes entering the respective route parameters of the second segment 408 and the second SOC 406 as input into the vehicle model 308. The second SOC 406 may act as an initial SOC for the vehicle model 308. Similar to above, different subsets of route parameters of the second segment 408 may be entered as input to the different subsystems based on the specific route parameters ability to affect that particular subsystem. By entering the respective route parameters of the second segment 408 into the vehicle model 308, the vehicle model 308 outputs a third SOC 410.

The process 400 includes entering the respective route parameters of the final segment 412 and the third SOC 410 as input into the vehicle model 308. Similarly, the third SOC 410 may act as an initial SOC for the vehicle model 308 and different subsets of route parameters of the final segment 412 may be entered as input to the different subsystems based on the specific route parameters ability to affect that particular subsystem. By entering the respective route parameters of the final segment 412 into the vehicle model 308, the vehicle model outputs a final SOC 414.

It may be understood that plurality of segments may include additional segments or fewer segments without departing from the scope of the present disclosure. For example, the plurality of segments may include 30 segments. In the case of 30 segments, the process 400 may be similar in regards to the serial entering of route parameters of the respective segment and an initial SOC (or corresponding voltage) as input to the vehicle model 308.

Referring now to FIG. 5A, a schematic representation of a first portion 500 of an exemplary vehicle model (e.g., vehicle model 202) of a vehicle is shown. First portion 500 may include a driver model 530 and a vehicle controller model 502, each of which may receive various inputs and generate various outputs. In some cases, one or more outputs of driver model 530 and vehicle controller model 502 may be inputs into driver model 530, vehicle controller model 502, or a different sub-model of the vehicle model not shown in FIG. 5A.

Driver model 530 may model inputs into the vehicle model, such as, for example, commands made by a simulated operator of the vehicle. Driver model 530 may receive as input segmented route parameters 532, the segmented route parameters 532 being conditions that affect performance of a BEV vehicle traveling along a segment of a route. For a single simulation task (e.g., 100 simulations), the route may be one potential route of one or more potential routes with an initial location and a final destination wherein each of the one or more potential routes has the same initial location and the final destination. However, other simulation tasks may include different initial locations and final destinations.

Further, each route may be segmented such that each route comprises a plurality of segments. In some embodiments, the segmented route parameters 532 associated with the segment may include speed (e.g., desired speed, minimum speed, maximum speed, average speed, and the like), a desired change in speed of the vehicle commanded by a simulated driver of the vehicle, road grade expressed as a percentage, sinuosity, weather conditions, traffic conditions, wind conditions, and the like. However, segmenting the route based on uniformity of the route parameters along the segment may be challenging. In particular, data pertaining to specific route parameters may not be readily available. In one embodiment wherein specific route parameters are not readily available, the route parameters in regions may be estimated. More specifically, the route parameters may be estimated with algorithms and/or equations.

Based on vehicle speed, road grade, and other relevant route parameters over a duration (e.g., 1 second), driver model 530 may generate a torque demand 510. The duration may be a portion of the total duration for the vehicle to finish the segment in some embodiments (e.g., travel along a portion of the segment). In other embodiments, the duration may be the total duration for the vehicle to finish the segment. Driver model 530 may also receive as input a glider output 534, where the glider output 534 is an output of the vehicle model. The glider output 534 may be a speed, a change of speed of the vehicle, and other relevant route parameters after a first flow of data through the vehicle model (e.g., over the duration for the vehicle to finish either a portion of the segmented or to finish the entire segment). The glider output 534 is described in greater detail below in reference to FIG. 5B.

Torque demand 510 may be an input into vehicle controller model 502. Vehicle controller model 502 may receive additional inputs, such as a transmission output 512, a motor output 514, an auxiliary load output 516, and a battery/fuel cell output 518. Transmission output 512 and motor output 514 may be outputs of a transmission model and a motor model, respectively, as described in greater detail below in reference to FIG. 5B. Each of the transmission output 512, the motor output 514, the auxiliary load output 516, and the battery/fuel cell output 518 may be based on route parameter data over a portion of the total duration to finish the segment or the total duration to finish the segment.

Based on the inputs (e.g., torque demand 510, transmission output 512, motor output 514, auxiliary load output 516, and battery/fuel cell output 518), vehicle controller model 502 may generate a plurality of outputs, including a gear selection 520 (e.g., to be inputted into a transmission model of the vehicle model), a motor control 522 (e.g., to be inputted into a motor model of the vehicle model), a brake control 524 (e.g., to be inputted into a driveline model of the vehicle model), and an energy management output 526. Energy management output 526 may be a control signal inputted into a battery/fuel cell 540 and at least in some examples may represent an amount of recovered energy to be stored in battery/fuel cell 540.

Battery/fuel cell 540 may output battery/fuel cell output 518, which may be inputted into vehicle controller model 502, based on energy management output 526. An additional input into battery/fuel cell 540 may be a thermal system output 551 of a thermal system 550, based on battery/fuel cell output 518. The thermal system output 551 may also be an input into an auxiliary load element 552, which may generate the auxiliary load output 516. The auxiliary load output may be inputted into vehicle controller model 502. Thus, inputs and outputs of vehicle controller model 502, battery/fuel cell 540, thermal system 550, and auxiliary load element 552 may comprise an energy regeneration feedback loop 554.

In this way, a state of charge (SOC) of battery/fuel cell 540 may be determined based on a predicted voltage of the battery/fuel cell 540 during the portion of the segment or the entire segment. The predicted voltage may be determined based on torque demand 510, a transmission model, a driveline model, a vehicle model, energy consumed by the thermal system 550 and the auxiliary load element 552, and energy regeneration from regenerative braking as the vehicle simulation travels along the portion of the segment or the entire segment. The SOC (e.g., corresponding predicted voltage) may be used as input (e.g., an initial battery level) for a next portion of the segment or next segment depending on the embodiment. As such, the SOC of the battery/fuel cell 540 of the vehicle at the end of each segment may be determined and used to predict the SOC of the battery fuel/cell at the end of a subsequent segment along the route. More specifically, a final state of charge of the battery/fuel cell 540 may considered the state of charge of the battery/fuel cell 540 once the last segment is entered into the vehicle model.

Referring now to FIG. 5B, a schematic representation of a second portion 560 of a vehicle model (e.g., vehicle model 202) of a vehicle is shown. Second portion 560 may include a powertrain model 562 and a vehicle model 570, each of which may receive various inputs and generate various outputs. In some cases, one or more outputs of powertrain model 562 and vehicle model 570 may be inputs into vehicle model 570 and powertrain model 562, respectively, driver model 530, and/or vehicle controller model 502 of FIG. 5A. It should be appreciated that while in the depicted vehicle model the vehicle is a battery-electric vehicle (BEV), in other embodiments the vehicle may not be a BEV and the vehicle model may include additional and/or other components, such as an internal combustion engine (ICE).

Powertrain model 562 may represent various components in an electrified powertrain of the vehicle, including electric machines, gear boxes, final drives, high voltage/low voltage (HV/LV) batteries, direct current to direct current (DC-DC) converters, and the like. In various embodiments, powertrain model 562 may be divided into one or more subsystems, based on data published by relevant component teams. For example, powertrain model 562 may include a motor model 564, which may model an electric motor of the vehicle; a transmission model 566, which may model a transmission of the vehicle; and a driveline model 568, which may model a torque supplied to wheels of the vehicle based on the electric motor, the transmission, and an application of one or more brakes of the vehicle. In various embodiments, powertrain model 562 may receive input from vehicle controller model 502 of FIG. 5A as well as segmented route parameters 532 that are relevant to operation of the respective component. As one example, certain traffic conditions and weather conditions may affect the performance of the driveline. By inputting route parameters that reflect the traffic and weather conditions into the driveline model 568, the driveline of a virtual vehicle may be more accurately simulated. Additionally, motor control 522 outputted by vehicle controller model 502 may be an input into motor model 564; gear selection 520 outputted by vehicle controller model 502 may be an input into transmission model 566; and brake control 524 outputted by vehicle controller model 502 may be an input into driveline model 568.

Battery/fuel cell output 518 may be an additional input into motor model 564. The battery/fuel cell output 518 may be a voltage of the battery/fuel cell 540. In one embodiment, the voltage of the battery/fuel cell 540 may be an initial voltage as a vehicle travels along a portion of a segment. In another embodiment, the voltage of the battery/fuel cell 540 may be an initial voltage as a vehicle travels along the entire segment. Based on battery/fuel cell output 518, output from transmission model 566, output from driveline model 568, and motor control 522, motor model 564 may generate an output that is received as an input into transmission model 566. Based on the output of motor model 564, the output from driveline model 568, and gear selection 520, transmission model 566 may generate an output that is received as input into the driveline model 568. Based on the output of transmission model 566 and brake control 524, driveline model 568 may generate an output that is received as input into vehicle model 570.

Vehicle model 570 may take characteristics of the vehicle such as tire size, frontal drag, vehicle mass, and the like, and model various road loads acting on the vehicle at different points in a drive cycle or maneuver. The characteristics may be included in vehicle model 570 as parameters that may be configured, for example, based on a configuration file associated with the vehicle model, as described below in reference to FIG. 5C. Vehicle model 570 may generate a glider output 534, which may comprise operational state data of the vehicle as a result of a flow of data through the vehicle model. For example, glider output 534 may include a speed of the vehicle, a selected gear of the vehicle, a state of one or more brakes of the vehicle, and the like. In another example, the glider output 534 may output an estimated voltage of the battery/fuel cell 540 at an end of the portion of the segment or at an end of the entire segment. Glider output 534 may be inputted back into driver model 530, as described above in reference to FIG. 5A, to finish a global feedback loop. In this way, the vehicle model 570 may estimate a final voltage (and thus a final state of charge (SOC)) of the battery/fuel cell 540 after a vehicle travels along a segment. The estimated final voltage may be then used as the initial voltage for a subsequent segment of the pre-determined route. By using the final voltages of the battery/fuel cell 540 for each segment as input, a final overall voltage of the vehicle at the final destination of the route may be determined. Glider output 534 may also be provided as an additional input into transmission model 566 and/or driveline model 568 in a powertrain feedback loop 572 with powertrain model 562.

Vehicle model 202 may be generated based on historical and/or statistical data (e.g., vehicle operational data and instrumentation data) collected from one or more actual vehicles operated using a dynamometer at a lab of a manufacturer of the one or more vehicles. The vehicle operational data collected to generate the vehicle model 202 may be obtained from a variety of sensors positioned on the one or more vehicles. The sensors may include but are not limited to an accelerator pedal position sensor, vehicle speed sensor, steering wheel position sensor, motor sensors (e.g., motor speed, motor torque, motor power), battery sensors (e.g., battery state of charge, battery temperature, battery output), transmission sensors (e.g., input shaft speed, output shaft speed), suspension system sensors, wheel speed sensors, braking sensors (e.g., brake pedal position, friction brake torque), auxiliary load sensors (e.g., sensors configured to measure an electric load placed by one or more auxiliary loads such as the vehicle HVAC system and vehicle cabin electric loads), and environment condition sensors (e.g., ambient temperature, ambient pressure, ambient humidity). The instrumentation data may include data generated at the dynamometer, such as road load and road grade, as well as output from sensors positioned on the one or more vehicles that may not be present on typical deployed vehicles. Further, vehicle operational data may be obtained from a vehicle controller of each of the one or more vehicles. The vehicle operational data obtained from the vehicle controller(s) may include but is not limited to commanded vehicle operating parameters (e.g., commanded motor torque, commanded brake torque, commanded regenerative braking torque and/or commanded regenerative braking torque/friction braking torque ratio) and operator inputs (e.g., activation of cabin heating or cooling, transmission gear shifts).

FIG. 5C shows how a vehicle model 584 may be used by elements of a cloud ecosystem 580, where vehicle model 584 may be a non-limiting embodiment of the vehicle model of FIGS. 5A and 5B and/or vehicle model 202 of FIG. 2, and cloud ecosystem 580 may be a non-limiting embodiment of cloud ecosystem 116 of FIG. 1. As described above in reference to FIG. 1, vehicle model 584 may be uploaded to cloud ecosystem 580 to be used by a simulation engine 595 (e.g., simulation engine 118) to generate a plurality of virtual vehicles for data gathering purposes.

Cloud ecosystem 580 may include a processor 581, a simulation engine 595, vehicle model software 582, and a memory 592. In various embodiments, vehicle model 584 may be a computer model embodied in vehicle model software 582. Vehicle model software 582 may additionally include a configuration file 586. Cloud ecosystem 580 may be communicatively coupled to a computing device 574 comprising a user interface (UI) 576 and a fleet management system (FMS) 578, which may be an embodiment of FMS 104. The UI 576 and the FMS 578 may be communicatively coupled to enable a user 590 to enter various input parameters and initialize the simulations via the UI.

Various parameters of vehicle model 584 may be defined in configuration file 586. For example, configuration file 586 may include settings for vehicle characteristics, such as a type of a vehicle, an age or a number of miles driven by the vehicle, a size of the vehicle, a weight of the vehicle, and the like for all vehicles in a fleet of vehicles. Configuration file 586 may include settings for drive cycle and/or driving route including length, duration, grade, and/or other characteristics. Configuration file 586 may further establish maximum or minimum settings for operation of the modeled vehicle, such as a maximum speed, minimum turning radius, minimum braking distance, and the like. Configuration file 586 may include settings for weather conditions, road conditions, time of day, and/or other characteristics of an environment of the modeled vehicle for an assigned drive cycle (e.g., on one or more potential routes). It should be appreciated that the examples provided herein are for illustrative purposes, and additional or different settings may be included in configuration file 586 without departing from the scope of this disclosure.

During creation of vehicle model 584, the user 590 (e.g., a software engineer in a laboratory of a vehicle manufacturer) may configure the parameters of vehicle model 584 by adjusting one or more settings of configuration file 586. For example, user 590 may open configuration file 586 on a display device (e.g., a monitor) and manually enter in settings of configuration file 586 via a keyboard or another input device. Alternatively, user 590 may adjust the one or more settings of configuration file 586 via UI 576, for example, by interacting with virtual controls of UI 576, or dialog boxes, wizards, and/or similar graphical user elements.

After vehicle model 584 has been configured by user 590, user 590 may interact with vehicle model software 582 to run a simulation of vehicle model 584, via UI 576, based on the settings of configuration file 586. The simulation of vehicle model 584 may be performed for one or more potential routes for each route of a plurality of routes, wherein each potential route is segmented into a plurality of segmented by a segmentation model, which is described below in FIG. 6. During the simulation of each segment, various inputs and outputs of sub-models and/or subsystems of vehicle model 584 may be generated, which may be saved as model output data 594 of memory 592. The sub-models and/or subsystems of vehicle model 584 may include driver model 530 and vehicle controller model 502 of FIG. 5A, and powertrain model 562 and vehicle model 570 of FIG. 5B. During testing of vehicle model 584, various configurations may be tested and analyzed to determine a suitable set of initial configuration parameters for simulation on a larger scale, within cloud ecosystem 580.

Vehicle model 584 may be uploaded to cloud ecosystem 580 bundled within vehicle model software 582. Within cloud ecosystem 580, simulation engine 595 may interact with vehicle model 584 via configuration file 586. For example, simulation engine 595 may include an instance management module 596 and a configuration generator 597. Instance management module 596 may be used to generate and track a plurality of virtual vehicles, each virtual vehicle based on vehicle model 584. The plurality of virtual vehicles may be vehicles included in a fleet of vehicles. Tracking the plurality of virtual vehicles may include tracking model output data 594 for each virtual vehicle instance (e.g., each time a simulation with a virtual vehicle is performed). Configuration generator 597 may be used to define parameters for each virtual vehicle instance. For example, configuration generator 597 may generate a first set of settings for a first virtual vehicle instance, a second set of settings for a second virtual vehicle instance, a third set of settings for a third virtual vehicle instance, and so forth. In various embodiments, the first set of settings, the second set of settings, and the third set of settings, and subsequent sets of settings may be randomly selected within pre-established ranges based on one or more algorithms of simulation engine 595.

As an example, the first set of settings for the first virtual vehicle instance generated by configuration generator 597 may include a first set of equation parameters and weights for various vehicle subsystems. The first virtual vehicle may be a first vehicle in a fleet of vehicles. In some examples, the equation parameters may represent different vehicle parameters under different conditions, such as vehicle speed, vehicle weight, brake pedal position, battery conditions (e.g., state of charge), and various road conditions (e.g., that impact friction, such as whether the road is wet, the road is covered in snow or ice, etc.). However, ideal equations for the various vehicle subsystems may be impossible for a human to manually determine given that the number of equation parameters that could be included in the equation is relatively large and thus the number of possible combinations of parameters and weights is high.

Accordingly, the virtual vehicles may be assigned various different settings and the data collected from the simulations may be used to train a ML model to determine which equation parameters and/or weights to include in the various subsystem equations, which may also change as conditions change. Thus, the first set of parameters and weights for the first virtual vehicle (e.g., a first vehicle of a fleet) instance may include some or all of the possible equation parameters and respective weights assigned to each parameter. The second set of settings for the second virtual vehicle (e.g., a second vehicle of a fleet) instance may include a different, second set of equation parameters and weights, the third set of settings for the third virtual vehicle (e.g., a third vehicle of a fleet) instance may include a still further different, third set of equation parameters and weights, and so forth. In other examples, the data collected from the simulations may be used to train a super ML model that mimics a plurality of real vehicles under a plurality of different conditions, as explained above, and the super ML model, once trained, may be used to generate training data for training a specialized ML model to determine which equation parameters and/or weights to include in the vehicle subsystem equations.

The model output data 594 for each vehicle instance may include output data that can be entered as input to the ML model to determine the vehicle subsystem equations as explained above. As such, the model output data 594 may include, for each simulated potential route, the vehicle control parameters that may be adjusted or optimized.

Turning to FIG. 6, a process 600 for training a segmentation model 618 is illustrated. The segmentation model 618 may be trained to segment one or more potential routes for one route of a plurality of routes based on uniformity of route parameters along the respective potential route. The segmentation model 618 may be an embodiment of segmentation model 304 of FIG. 3. The process 600 may be implemented by one or more computing systems, such as simulation system 200 of FIG. 2, to train the segmentation model 618 to group coordinates that comprise a potential route based on similar route parameters, the grouped coordinates may be one segment of a plurality of segments. Once trained, the segmentation model 618 may be used to segment a potential route acquired with Azure Maps and OpenStreetMap, in accordance with one or more operations described in greater detail below in reference to FIGS. 7-9.

The process 600 includes determining one or more potential training routes 602 with Azure Maps and obtaining coordinates that define the one or more potential training routes. The one or more potential training routes 602 may be determined by entering a training route as input to Azure Maps. As described above, the training route may comprise an initial location and a final destination wherein a real vehicle (e.g., BEV truck) may stop at various locations prior to reaching the final destination. In some embodiments, the initial location may be the same location as the final destination and the initial location may be a central recharging location. More specifically, the coordinates of the initial location, the final destination, and each stop may be entered as input. In response to entering the coordinates as input, Azure Maps may output route training data, such as directions that includes types of road ways, street names, coordinates of operational maneuvers, and the like.

The process 600 includes performing coordinate mapping 604 wherein coordinates obtained from Azure Maps are mapped to coordinates of OpenStreetMap. In particular, the data elements (e.g., nodes, ways, and relations) of OpenStreetMap include one or more coordinates in addition to various route training parameters. Additional data regarding specific coordinates in Azure Maps may be obtained with OpenStreetMap by identifying nodes, ways, and relations with the specific coordinates. In this way, training route parameters, including weather conditions, traffic conditions, wind conditions, and the like may be accessed for each potential training route.

The process 600 includes generating a plurality of training sets of data using a dataset generator 606. The plurality of training sets of data may be stored in a training module 608. The training module 608 may be the same as or similar to the ML module 210 of simulation system 200 of FIG. 2. The plurality of training sets of data may be divided into training sets 610 and test sets 612. Each training set of training sets 610 and test sets 612 may include the nodes, ways, and/or relations for each potential training route.

Once each set is generated, each set may be assigned to either the training sets 610 or the test sets 612. In an embodiment, the set may be assigned to either the training sets 610 or the test sets 612 randomly in a pre-established proportion (e.g., 90%/10% training/test, or 85%/15% training/test). It should be appreciated that the examples provided herein are for illustrative purposes, and sets may be assigned to the training sets 610 dataset or the test sets 612 dataset via a different procedure and/or in a different proportion without departing from the scope of this disclosure.

A number of training sets 610 and test sets 612 may be selected to ensure that sufficient training data is available to prevent overfitting, whereby an initial segmentation model 614 learns to map features specific to samples of the training set that are not present in the test set. The process 600 includes training the initial segmentation model 614 on the training sets 610. The process 600 may include a validator 616 that validates the performance of the initial segmentation model 614 (as the initial model is trained) against the test sets 612. The validator 616 may take as input a trained or partially trained model (e.g., the initial segmentation model 614, but after training and update of the model has occurred) and a dataset of test sets 612, and may output an assessment of the performance of the trained or partially trained segmentation model on the dataset of test sets 612.

Thus, the initial segmentation model 614 is trained on a training set wherein the training set includes one or more potential training routes 602, each potential training route comprising a plurality of data elements (e.g., nodes, ways, and/or relations) with various training route parameters associated with the data elements. In some embodiments, the plurality of training segments may be pre-determined, and an annotation may include all the coordinates of each training segment or the initial coordinate and the final coordinate that make up each training segment. In this way, each potential training route be annotated with information describing how the respective potential training route is segmented. The respective annotation may be considered as the ground truth plurality of training segments. The ground truth plurality of training segments may be compared with generated training segments output from the initial segmentation model to calculate a loss function that is used to adjust model parameters of the initial segmentation model. Other embodiments may utilize an unsupervised learning approach and may not utilize ground truth values to calculate the loss function.

Once the validator 616 determines that the segmentation model is sufficiently trained, the segmentation model may be stored in the simulation system 200 of FIG. 2. The segmentation model 618, when deployed, may identify coordinates with similar route parameters to segment a potential route. Newly-acquired potential routes 601 may be subjected to coordinate mapping 604 and the outputted route data be entered as input to the segmentation model 618 to output a plurality of segments 620 for each potential route. The plurality of segments 620 may be used as input for a vehicle model, which may be an embodiment of vehicle model 202 of FIG. 2.

Turning to FIG. 7, a process 700 for training a vehicle model 718 is illustrated. The vehicle model 718 may be trained to simulate a plurality of vehicle subsystems of a vehicle traveling on each segment of a plurality of segments of a segmented potential route. The vehicle model 718 may be an embodiment of vehicle model 308 of FIG. 3 and may include a plurality of vehicle subsystem models as described in FIGS. 5A and 5B. The process 700 may be implemented by one or more computing systems, such as simulation system 200 of FIG. 2, to train the vehicle model 718 to simulate operation of a virtual vehicle and predict subsystem parameters by entering each training segment in a pre-determined order based on an order wherein the virtual vehicle travels along the potential training route chronologically and entering vehicle operation training data obtained from operation of a real vehicle. Once trained, the vehicle model 718 may be used to simulate the plurality of vehicle subsystems as a virtual vehicle operates on each segment, in accordance with one or more operations described in greater detail below in reference to FIGS. 8 and 9.

The process 700 includes obtaining the plurality of training segments 704 from a segmentation model, which may be an embodiment of the segmentation model 618, for each potential training route of one or more potential training routes 702. The one or more potential training routes 702 may be an embodiment of the one or more potential training routes 602 of FIG. 6. The process 700 includes generating a plurality of training sets of data using a dataset generator 706. The plurality of training sets of data may be stored in a training module 708. The training module 708 may be the same as or similar to the ML module 210 of simulation system 200 of FIG. 2. The plurality of training sets of data may be divided into training sets 710 and test sets 712. Each training set of training sets 710 and test sets 712 may include the plurality of training segments 704 and vehicle operation training data 724. The vehicle operation training data 724 may be vehicle operation training data of the plurality of vehicle subsystems obtained from vehicle sensors while driving on each training segment.

Once each set is generated, each set may be assigned to either the training sets 710 or the test sets 712. In an embodiment, the set may be assigned to either the training sets 710 or the test sets 712 randomly in a pre-established proportion (e.g., 90%/10% training/test, or 85%/15% training/test). It should be appreciated that the examples provided herein are for illustrative purposes, and sets may be assigned to the training sets 710 dataset or the test sets 712 dataset via a different procedure and/or in a different proportion without departing from the scope of this disclosure. In some embodiments, the training sets 710 and the test sets 712 may include a plurality of subsets, wherein each subset includes vehicle operation training data and training segments (e.g., training route parameters) for a specific vehicle subsystem (e.g., the vehicle subsystems described in FIGS. 5A and 5B). In this way, the vehicle subsystem models may be trained individually with relevant training route parameters of the training segments and relevant vehicle operation training data.

A number of training sets 710 and test sets 712 may be selected to ensure that sufficient training data is available to prevent overfitting, whereby an initial vehicle model 714 learns to map features specific to samples of the training set that are not present in the test set. The process 700 includes training the initial vehicle model 714 on the training sets 710. The process 700 may include a validator 716 that validates the performance of the initial vehicle model 714 (as the initial model is trained) against the test sets 712. The validator 716 may take as input a trained or partially trained model (e.g., the initial vehicle model 714, but after training and update of the model has occurred) and a dataset of test sets 712, and may output an assessment of the performance of the trained or partially trained vehicle model on the dataset of test sets 712.

Thus, the initial vehicle model 714 is trained on a training set wherein the training set includes the plurality of training segments 704, their respective route training parameters, and vehicle operation training data 724. For the first training segment, the vehicle operation training data 724 may be initialization parameters for the plurality of vehicle subsystems, such as an initial voltage of a battery/fuel with a corresponding state of charge (SOC), and the like. Other vehicle operation training data 724 may be considered as the ground truth vehicle subsystem training parameters. The ground truth vehicle subsystem training parameters may be compared with generated vehicle subsystem training parameters output from the initial vehicle model to calculate a loss function that is used to adjust model parameters of the initial vehicle model, or rather each vehicle subsystem model.

Once the validator 716 determines that the vehicle model is sufficiently trained, the vehicle model may be stored in the simulation system 200 of FIG. 2. The vehicle model 718, when deployed, may predict vehicle subsystem parameters, such as voltage or SOC of a fuel cell battery, and the like for each segment in the pre-determined order wherein the plurality of segments 704 are entered into the vehicle model. Newly-acquired potential routes 701 and newly-acquired plurality of segments 703 may be entered as input to the vehicle model 718 to output a battery state of charge (SOC) 720 and vehicle operation parameters 722 for each potential route.

Turning to FIG. 11, a method 1100 for operating a fleet of vehicles (e.g., a fleet of BEV vehicles or trucks) having a central recharging location based on simulation results from a physics-based simulation system. The central recharging location is the same and located at the same physical address as the initial location and the final destination. The physics-based simulation system may be an embodiment of the physics-based simulation system described in FIG. 2. The fleet of vehicles may include at least two vehicles. However, different embodiments of the fleet of vehicles may include two or more vehicles. In particular, different vehicles in the fleet may be selected and sent on different routes of a plurality of routes based on a predicted completion rate generated by the physics-based simulation system. The same vehicle may also be sent on other routes of the plurality of routes.

At 1102, the method 1100 includes operating a fleet of vehicles in response to a completion rate being greater than a confidence threshold. As described below in FIG. 8, the simulation system may generate a statistical summary report that includes a confidence interval for the completion rate for each potential route for each vehicle. More specifically, the completion rate refers to a percentage that describes the likelihood that the vehicle returns to the central recharging location at the end of the route without external recharging. In this way, the fleet of vehicles may operate more efficiently since charging only happens in a controlled central location, which, in turn, increases the longevity of the battery of the vehicle since slow, controlled charge is used instead of high speed charging in the field. Additionally, charging in a controlled center location extends the life of the fleet and provides efficient use of energy as overnight charging can be more efficient for the grid than during high demand times. A lower bound of a confidence interval for the completion rate may be compared with a confidence threshold, such that particular vehicles with completion rates that are greater than the confidence threshold may potentially be selected and sent on certain routes of the plurality of routes.

In particular, operating a fleet of vehicles based on the completion rate may include operating at least a first vehicle of the fleet and a second vehicle of the fleet with different physical characteristics (e.g., age, wear, etc.) in response to a completion rate being greater than a confidence threshold. Each of the first vehicle and the second vehicle may only externally recharge at the central recharging location without external recharging occurring on the respective route of each of the first vehicle and the second vehicle. The completion rate is generated b7, for each of the first vehicle and second vehicle, entering the route of a plurality of routes via a fleet management system (FMS) communicatively coupled to a physics-based simulation system, validating each route via the physics-based simulation system, the physics-based simulation system comprising a vehicle model that simulates operation of a virtual vehicle and a segmentation model, storing collected simulation data in a data lake, and generating a statistical summary report based on simulation data stored in the data lake and displaying the statistical summary report to a user. The method described below with respect to FIG. 8 illustrates the method for generating the completion rate in detail.

At 1102, the method includes selecting each vehicle to send on one route of a plurality of routes based on the completion rate. In particular, one of the first vehicle and the second vehicle may be selected in response to the completion rate of one of the first vehicle and the second being greater than a confidence threshold and may be sent on a specific route of the plurality of routes. In particular, the vehicle with the highest completion rate may be sent on the specific route. The unselected vehicle may be sent on another route of the plurality of routes based on the vehicle having a highest completion rate for that particular route. For example, the lower bound of the confidence interval of the completion rate of the first vehicle for a route may be 98% and the lower bound of the confidence level of the completion rate of the second vehicle for the same route may be 96%. The value of the confidence threshold may be 95%. Accordingly, both of the first vehicle and the second vehicle are expected to finish the route. However, the first vehicle is selected for the route and the second vehicle is selected for another route wherein the second vehicle has the highest completion rate.

In another embodiment wherein a route is not matched to either of the first vehicle and the second vehicle due to a completion rate not being greater than the confidence threshold, a hybrid vehicle or internal combustion engine (ICE) vehicle may be sent on the route in response to neither of the first vehicle and the second vehicle having a completion rate greater than the confidence threshold. As an example, the lower bound of the confidence interval of the completion rate of the first vehicle for the respective route may be 92% and the lower bound of the confidence level of the completion rate of the second vehicle for the respective route may be 90%. Since, the value of the confidence threshold is 95%, neither of the first vehicle and the second vehicle may be selected for the respective route. The method 1100 then ends.

It may be understood that the fleet of vehicles may include more than two vehicles and the plurality of routes may include more than two routes without departing from the scope of the present disclosure. For example, the fleet of vehicles may include 25 vehicles and the plurality of routes may include 75 routes, which may be completed at different times. Each of the 25 vehicles may be assigned to one or more routes of the 75 routes based on the completion rate being greater than the confidence threshold.

A method 800 for determining a predicted completion rate of a BEV vehicle based on simulations of a fleet route physics-based model is shown in FIG. 8. The method 800 may be performed by instructions configured, stored, and executed in memory by at least one processor to receive a route of a plurality of routes based on user preferences from a fleet management system (FMS), validate the route, run a simulation of a virtual vehicle (or fleet of virtual vehicles) traveling on the route, generate simulation data, perform a statistical analysis based on the simulation data, and generate a statistical summary report to output to the FMS communicatively coupled to a cloud ecosystem over a network. In this way, a fleet manager or user of the FMS may employ BEV vehicles based on the predicted completion rate included in the statistical summary report according to the method described in FIG. 11 without exceeding an accepted discharge level of the battery or without unplanned stops to charge the battery

At 802, the method 800 includes for each vehicle in a fleet of vehicles, entering a route via the fleet management system (FMS). Each vehicle in the fleet of vehicles may have different physical characteristics that affect performance of the respective vehicle on the route. The route may be received in response to a user interacting with a user input device communicatively coupled to a user interface. In this way, the route may be defined based on an initial location, a final destination, a number of anticipated stops, and desired route conditions during operation of the BEV vehicle. The initial location and final destination may be the same physical location and/or physical address to enable the virtual vehicle to charge at a central recharging location. The desired route conditions may include a plurality of input parameters, such as weather conditions, wind conditions, traffic conditions, offloading strategy, and the like. The plurality of input parameters may be preferred weather conditions, wind conditions, and the like during operation of the BEV vehicle (e.g., BEV truck). The BEV vehicle may operate more efficiently under certain conditions, including dry road conditions and/or particular wind speeds and directions. For example, for a particular route, the BEV vehicle may operate with increased efficiency when the road conditions of the route are rainy and slippery compared to snowy/icy and slippery. Accordingly, the user may select dry roads as a preferred route condition.

In some embodiments, the plurality of input parameters may be ranked based on preferred weather conditions, wind conditions, offloading strategy, and the like when operating the BEV vehicle, which may be one vehicle in a fleet. In this way, the simulation system may select from one or more potential routes based on the preferred conditions as applicable. More specifically, the simulation engine may simulate the virtual vehicle traveling on various potential routes, as described herein. The potential routes with the preferred conditions may be prioritized over potential routes without the preferred conditions in the statistical analysis summary. In other embodiments, input parameters may not be received at a user input device and in response to not receiving user input, the simulation engine may select from the one or more potential routes based on real-time or near real-time conditions or historical conditions and/or randomly.

At 804, the method 800 includes validating the route via the simulation system. The simulation system may include a simulation engine in a cloud environment, as described above with respect to FIG. 2, communicatively coupled via a cloud over a network to the fuel management system (FMS) and various data sources. As mentioned above, in some embodiments, the plurality of input parameters may be received at the user input device. In other embodiments, the plurality of input parameters may not be received at the user input device. Instead, the plurality of input parameters may be randomly selected by the simulation system and/or may be based on real time or near real-time data and/or historical data.

The simulation system may further transmit the route to Azure Maps for validation whereby data regarding the route, or rather the one or more potential routes, is received and transmitted to the simulation system. Data regarding the one or more potential routes may be received from OpenStreetMap and segmented with machine learning (ML) based on uniform or nearly uniform route parameters according to the embodiments described herein. Topographic and geographic location data for the one or more potential routes may be received from the plurality of data sources. The data sources may include Azure Maps, OpenStreetMap, and online databases. Topographic and geographic location data may include traffic density, population density, traffic signal updates, and the like. As such, the input parameters entered as input to the FMS and the data obtained from the various data sources may be input into the fleet route physic-based model of the simulation system.

In this way, the simulation system may run a plurality of simulations to simulate a virtual vehicle (or fleet of vehicles) traveling along the route. More specifically, the plurality of simulations may simulate operation of a virtual vehicle of a BEV vehicle (e.g., BEV truck) on the one or more potential routes. As one example, for each vehicle of the fleet, the plurality of simulations may include a hundred different simulations for the one or more potential routes. In some embodiments, each simulation of the plurality of simulations may be based on real-time data, near real-time data, and/or historical data. In particular, the real-time data, near real-time data, and/or historical data may be various route parameters, such as traffic conditions, weather conditions, and wind speed, and the like.

In other embodiments, each simulation of the plurality of simulations may utilize different combinations of the plurality of input parameters to encompass various potential driving conditions within the region defining the route. In this way, the simulations may encompass a wide variety of driving conditions along the one or more potential routes. In additional embodiments, a same potential route may be simulated one or more times for the same vehicle or different vehicles in a fleet. The same potential route comprises a route with a same number of stops that occur in a same order, a same initial location, and a same final destination. However, simulations of the same potential route may be performed under different route parameters (e.g., different driving conditions). Each simulation may generate data and the data generated by the plurality of simulations may be combined to generate a statistical summary report of the simulation data.

At 806, the method 800 includes storing collected simulation data in a data lake. As described herein, each simulation generates data and a summary based on the simulation data may be generated as well. For example, the simulation data may include data regarding anticipated time to finish the route, state of charge (SOC) of the battery of the virtual vehicle, other vehicle subsystem parameters, and the like. In some embodiments, the simulation system may be communicatively coupled to the data lake. In particular, the simulation data generated may be transmitted to the data lake according to instructions configured, stored, and executed in at least one memory by at least one processor of a cloud ecosystem. In this way, the simulation data may be stored and accessed in real-time or near real-time.

At 808, the method 800 includes generating a statistical report and displaying the statistical report to the user. In some embodiments, the simulation system may access the simulation data output from the plurality of simulations and stored in the data lake. In particular, the simulation system may access the simulation data and utilize statistical models to generate a statistical summary report based on the simulation data. In particular, the statistical summary report may include a completion rate and a confidence interval for the completion rate. As described herein, the completion rate describes the likelihood or percentage that the virtual vehicle, and thus the real vehicle, may successfully finish the route. A lower bound of the confidence interval for the completion rate may be compared with a confidence threshold as described above in FIG. 11. The confidence threshold is selected such that it ensures accurate allocation of real vehicles when operating a fleet of vehicles. More specifically, in some embodiments wherein route data, route parameter data, and other such data is unavailable and estimations are made when simulating operation of the virtual vehicle, the confidence threshold may be higher than in simulations wherein relevant route data, route parameter data, and other such data is available. Further, the confidence threshold may be higher to account for unexpected traffic conditions and/or weather, such as accidents or flash floods that make predicting completion rates difficult.

In some embodiments, it may include the time duration to finish the determined route. Further, the statistical summary report may include a summary of the expected weather conditions, traffic conditions, and wind conditions on segmented portions of the route and/or the entire route. After generating the statistical summary report, the simulation system may output the statistical summary report to the user via the FMS via the user interface. In this way, the user may evaluate the content of the statistical summary report to determine which potential routes have higher completion rates and/or have desired driving conditions. Further, the statistical summary report may give the user of the FMS insight about whether the virtual vehicle, and thus, the real vehicle may successfully finish the route. As such, the user may operate the fleet of vehicles (e.g., fleet of BEV vehicles, and more specifically, BEV trucks) according to the method described in FIG. 11. The method 800 then ends.

As shown in FIG. 9, a method 900 for operating a simulation system based on a fleet route physics-based model that simulates operation of a real vehicle (e.g., a BEV vehicle). The method 900 may be performed by instructions configured, stored, and executed in memory by at least one processor to simulate operation of a virtual vehicle on one or more potential routes. The simulation system may include a simulation engine communicatively coupled to memory and the at least one processor that executes instructions that cause the processor to validate a plurality of input parameters entered as input into a fleet management system (FMS), validate the route, collect topographic and geographic location data, and run a plurality of simulations over the route, and collect data generated from the plurality of simulations.

At 902, the method 900 includes obtaining input parameters entered as input into the fleet management system (FMS). The simulation system may obtain a plurality of input parameters via the FMS. As described herein, user input may be received at a user input device communicatively coupled to a user interface of a computing device wherein the FMS is installed. The user input may cause the plurality of input parameters to be selected. As described herein, the plurality of input parameters may be preferred driving conditions as requested by a user of the FMS. In some embodiments, user input that causes the plurality of input parameters to be selected may not be received. In this case, the simulation system may randomize the plurality of input parameters.

In this way, a plurality of simulations may be performed wherein each simulation of the virtual vehicle (or fleet of vehicles) occurs under different driving conditions as defined by the input parameters and/or route parameters. For example, the plurality of input parameters may be randomized. As another example, randomization of the plurality of input parameters may include randomizing a subset of historically selected input parameters instead of all possible input parameters. In other embodiments wherein user input that causes the input parameters to be selected is not received, the simulation system may perform the simulation based on real-time or near real-time data and/or historical data instead of input parameters.

At 904, the method 900 includes obtaining route data for one or more potential routes with Azure Maps. In some embodiments, the route data may be obtained by inputting an initial location, a final destination, and a plurality of stops into Azure Maps. In response to entering the initial location, the final destination, and the plurality of stops as waypoints, Azure Maps may output one or more potential routes with directions to the final destination. The directions may include recommended operation maneuvers of the real vehicle for specific road/streets, a road type, a junction type, a turning angle, a distance of a particular operation maneuver, and a time to finish the particular operation maneuver. In the case wherein the real vehicle is a BEV truck of a fleet, the potential routes include roads that the BEV truck may operate on and may perform operation maneuvers successfully. In one example, some roads may not be accessible to the BEV truck due to a height of the BEV truck exceeding accepted height clearances. As another example, some roads that includes bridges may not be accessible to the BEV truck since a width of the BEV truck may exceed a lane width of the road. Additionally, some operation maneuvers may not be finished by the BEV truck due to an unsuitable turning radius of the BEV truck.

For each potential route, in addition to the directions, Azure Maps may output a distance of the potential route, a time to finish the potential route, a time delay due to traffic conditions, a departure time, an arrival time, coordinates (e.g., longitude and latitude) of the road path, and the like. Azure Maps may further output weather conditions and traffic conditions along the one or more potential routes. The weather conditions may include temperature, wind direction, wind speed, visibility, air pressure, hazards due to the weather conditions (e.g., storms or heavy winds), and the like. The traffic conditions may include relative or absolute traffic data (e.g., speed data) due to construction, road closures, accidents, and congestion. The route data (e.g., route parameters) for the one or more potential routes that is output from Azure Maps may be received and relevant route parameters may be entered as input to a segmentation model or a vehicle model as described above with respect to FIGS. 3-7.

At 906, the method 900 includes obtaining route parameters for the one or more potential routes with OpenStreetMap. More in depth information regarding each potential route of the one or more potential routes may be obtained from OpenStreetMap. By mapping coordinates defining each potential route in Azure Maps to the same coordinates in OpenStreetMap, geographical and geospatial information regarding the potential route may be obtained and the one or more potential routes may be defined in OpenStreetMap. In particular, the one or more potential routes may be defined based on coordinates, street names, and the like. As described above with respect to FIG. 7, OpenStreetMap includes nodes, ways, and relations. Nodes, ways, and relations include tags that provide geographical and geospatial data at a single coordinate (e.g., node) or at a plurality of coordinates (e.g., way). In particular, the geographical and geospatial data may include a type of road, a speed of the roadway, sinuosity of the roadway, a road grade of the roadway, and the like.

As an example, a first coordinate on a potential route may be a first type of roadway and may have a first type of roadway, a first sinuosity, a first road grade, etc. and a second coordinate on the potential route may be a second type of roadway and may have a second sinuosity, a second road grade, etc. The first coordinate is different than the second coordinate with regards to the geographical and geospatial data associated with the respective coordinate. Accordingly, the geographical and geospatial landscape of different coordinates may affect operation of a real BEV vehicle (e.g. BEV truck) and the vehicle subsystems differently. In turn, this may result in different rates of energy consumption when the BEV vehicle operates on a portion of the route that includes the first coordinate compared to a portion of the route that includes the second coordinate.

The geographical and geospatial data may be received from the relevant nodes and ways and used as route parameters. In particular, for a machine learning (ML) approach, the coordinates and the respective route parameters associated with specific coordinates may be used as training data for a segmentation model and may be entered as input to a trained segmentation model that identifies coordinates on one potential route that have similar geographical and geospatial data, and thus, operation of the real vehicle and vehicle subsystems behave similarly.

By utilizing Azure Maps and OpenStreetMap to obtain routing data and geospatial data and temporarily storing the data in memory of the cloud ecosystem (e.g., cloud ecosystem 116), memory storage may be more efficiently managed. Rather than devoting addresses in memory to routing data and geospatial data that varies based on a time of day, time of year, and other variable factors, memory may be devoted to less variable data, such as segmentation model parameters and vehicle model parameters.

At 908, the method 900 includes entering the route and route parameters as input to a segmentation model the route via OpenStreetMap. The segmentation model may include one or more suitable ML model architectures, such as neural networks, random forest, decision trees, Bayesian networks, etc. In some embodiments, the segmentation may be a classifier model that identities contiguous coordinates with similar route parameters (e.g. similar geographical and geospatial properties). In this way, contiguous coordinates with similar route parameters may be grouped to form one segment of a plurality of segments. In other embodiments wherein there is lack of adequate Azure Maps or OpenStreetMap data for segmentation, relevant route parameters or route data may be estimated with algorithms or mathematical equations. For example, a length of highly sinuous roads may be approximated with straight roads that have similar vehicle subsystem operation behavior. The plurality of segments may be ordered based on an order wherein the vehicle arrives at each segment of the plurality of segments (e.g. chronologically).

At 910, the method 900 includes collecting topographic and geographic location information. After obtaining route data and parameter data and segmenting the one or more potential routes based on the route data and parameter data, topographic information for each segment of the plurality of segments may be collected from online databases. Topological data and geographic location data may be collected to provide data about the landscape, including elevation of topographical features (e.g., mountains, hills, valleys, cities, etc.), the location of streams, lakes, or rivers, density of vegetation (e.g., size of a forest), and the like. In this way, by considering topographical and geographical location data, the vehicle model may consider operational hindrances introduced during various segments of the potential route that may delay and/or reduce the likelihood or percentage that the virtual vehicle (or fleet of virtual vehicles) may successfully finish the route.

At 912, the method 900 includes entering route data as input to a vehicle model to predict battery voltage. The vehicle model may be an embodiment of the vehicle model described in FIGS. 5A and 5B. In addition to predicting battery voltage, the vehicle model is able to simulate operation of a virtual vehicle (or fleet of virtual vehicles) based on a real BEV vehicle (e.g., a BEV truck) and predict other vehicle operation parameters. The one or more potential routes may be simulated by performing a plurality of simulations using the vehicle model with a simulation engine according to instructions configured, executed, and stored in memory by at least one processor, as illustrated in FIG. 1. Further, the plurality of simulations may be configured and performed according to the physics-based simulation system referred to in FIG. 2.

As described above in FIG. 4, the plurality of simulations may be performed by serially entering one segment of the plurality of segments at a time, the plurality of segments belonging to one potential route of the one or more potential routes. Since the coordinates that comprise the segment have similar route parameters, coordinates of a start of the segment and an end of the segment as well as the route parameters for one coordinate may be entered as input to the vehicle model as described below. In this way, the computational load when simulating the virtual vehicle may be reduced. Further, the plurality of segments is entered in a pre-determined order based on wherein the vehicle (or each vehicle in a fleet of vehicles) arrives at each segment of the plurality of segments (e.g., chronologically). By entering the segments in the pre-determined order, the vehicle model may be able to predict the battery voltage (e.g., state of charge (SOC)) and other vehicle subsystem parameters at the end of the segment. In some embodiments, redundant data (e.g., route parameters and route data) for other coordinates in the segmented may be deleted after the vehicle model successfully predicts the battery voltage for the segmented, which may enable more efficient memory storage.

At 914, the method 900 includes sending simulation data to a data lake. The simulation data may a predicted state of charge (SOC) of the virtual vehicle battery for each potential route, time to finish each segment of the potential route, a time to finish the entire route a distance of each segment of the potential route, a completion rate for each potential route, as some examples. The data lake may be an embodiment of data lake 124 of FIG. 1. By storing the simulation data to the data lake, a fleet management system may be able to access the simulation data to generate a statistical summary report that is displayed to a user. The method 900 may then end.

FIG. 10 illustrates a timing sequence 1000 for utilizing a fleet route physics-based model to predict whether a battery electric vehicle (BEV) vehicle may finish a route. In some embodiments of the present disclosure, each step of the timing sequence 1000 may occur in real-time or near real-time. In other embodiments, the timing sequence 1000 may occur prior to initiation of the route and during the route prior to completion of the route.

At a time t0, in real-time or near real-time, validation of a fleet management system (FMS) is initialized when user input is received at a user interface. In some examples, the user input may include physical addresses for each of an initial location, a final destination, and each stop made along the route. At a time t1, the FMS designs a route based on the user input. More specifically, the FMS may determine coordinates for the physical addresses, which is entered as input to a simulation system. At a time t2, the user may customize the route conditions (e.g., a plurality of input parameters) based on weather, wind, temperature, and the like. However, in other embodiments of the present disclosure, the user may not customize the route conditions; instead, a simulation system may randomize the potential route conditions for a plurality of simulations.

At a time t3, the FMS transmits the route, and more specifically the coordinates of the initial location, the final destination, and each stop to the simulation system on the cloud over a network. The route may be received by the simulation system and validation of the route and the plurality of input parameters may be initiated at a time t4. At a time t5, the simulation system may access data sources, such as Azure Maps and OpenStreetMap, to obtain relevant route data, including a plurality of potential routes and route parameters. The simulation system may utilize the route data received from Azure Maps to map coordinates in Azure Maps with coordinates in OpenStreetMap. Further, the simulation system may receive route parameters from OpenStreetMap by identifying data elements such as nodes, ways, and relations that include the coordinates that define each potential route. Route data and route parameters may be entered as input to a segmentation model to segment (e.g., group coordinates) the potential route based on uniformity of the route parameters at t6.

At a time t7, when data obtained from Azure Maps and OpenStreetMap is insufficient, the simulation system may access an external database to obtain additional route parameters such as weather conditions, road conditions, and traffic conditions occurring in real-time or near real-time on the route. At a time t8, the simulation system may run a plurality of simulations (e.g., a hundred simulations) with a vehicle model that simulates a virtual vehicle operating over one or more potential routes. The vehicle model predicts vehicle subsystem parameters, which may be collected and stored in a data lake at a time t9. The FMS may access the data lake at a time t10 to perform statistical analysis on the collected data, generate a statistical summary report, and output the statistical summary to the user enabling the user to make informed decisions with regards to the fleet according to the method described in FIG. 11.

The technical effect of operating a fleet of vehicles (e.g., a fleet of BEV vehicles or trucks) having a central recharging location based on simulation results from a physics-based simulation system is that the fleet of vehicles may operate more efficiently since charging only happens in a controlled central location, which, in turn, increases the longevity of the battery of the vehicle since slow, controlled charge is used instead of high speed charging in the field. Further, charging in a controlled center location extends the life of the fleet and provides efficient use of energy as overnight charging can be more efficient for the grid than during high demand times. Additionally, performing simulations of a virtual vehicle with a physics-based simulation system that obtains and temporarily stores routing data and geospatial data from Azure Maps, OpenStreetMap in memory for route segmentation is that memory storage may be more efficiently managed. Rather than devoting addresses in memory to routing data and geospatial data that varies based on a time of day, time of year, and other variable factors, memory may be devoted to less variable data, such as segmentation model parameters and vehicle model parameters.

The disclosure also provides support for a method for operating a fleet of vehicles having a central recharging location, comprising: operating at least a first vehicle of the fleet and a second vehicle of the fleet with different physical characteristics in response to a completion rate being greater than a confidence threshold, where each of the first vehicle and the second vehicle only externally recharge at the central recharging location without external recharging occurring on a respective route of each of the first vehicle and the second vehicle and where the completion rate is generated by: for each of the first vehicle and the second vehicle, entering the respective route of a plurality of routes via a fleet management system (FMS) communicatively coupled to a physics-based simulation system, validating each route via the physics-based simulation system, the physics-based simulation system comprising a vehicle model that simulates operation of a virtual vehicle and a segmentation model, storing collected simulation data in a data lake, and generating a statistical summary report based on simulation data stored in the data lake and displaying the statistical summary report to a user, in response to the completion rate being greater than the confidence threshold, selecting one of the first vehicle and the second vehicle to send on one route of the plurality of routes based on a highest completion rate and sending an unselected vehicle on another route of the plurality of routes based on a next highest completion rate, and in response to a route not being matched to either of the first vehicle and the second vehicle due to the completion rate not being greater than the confidence threshold, sending a hybrid vehicle or internal combustion engine (ICE) vehicle on the route.

In a first example of the method, each route comprises an initial location, a final destination, a number of anticipated stops, and selectable input parameters and each of the initial location, the final destination, and the number of anticipated stops are entered as physical addresses to the FMS. In a second example of the method, optionally including the first example, the initial location and the final destination are the same and have a same physical address, a central recharging location is located at the initial location, and the selectable input parameters are desired route parameters. In a third example of the method, optionally including one or both of the first and second examples, route parameters include speed, road grade, wind conditions, traffic conditions, weather conditions, sinuosity, and other route parameters that affect operation of a real vehicle. In a fourth example of the method, optionally including one or more or each of the first through third examples, validating the route via the physics-based simulation system comprising the vehicle model that simulates operation of the virtual vehicle comprises: transmitting the route to Azure Maps to determine one or more potential routes, receiving route parameters from OpenStreetMap based on route data obtained from Azure Maps, segmenting the route based on uniformity of route parameters to generate a plurality of segments, receiving topographic data, geographic location data, and other route parameters from online databases, and simulating operation of the virtual vehicle by entering route parameters of the plurality of segments as input to the vehicle model.

In a fifth example of the method, optionally including one or more or each of the first through fourth examples, segmenting the route based on uniformity of route parameters to generate the plurality of segments is performed with the segmentation model for each of the one or more potential routes and both of the segmentation model and the vehicle model are machine learning (ML) models. In a sixth example of the method, optionally including one or more or each of the first through fifth examples, the route parameters entered as input to the vehicle model include the selectable input parameters received as user input, randomized input parameters, or input parameters based on real-time conditions, near real-time conditions, and historical conditions of the route. In a seventh example of the method, optionally including one or more or each of the first through sixth examples, the statistical summary report includes the completion rate, a confidence interval for the completion rate, a summary of expected weather conditions, traffic conditions, and wind conditions, and the like on segmented portions of the route and/or an entire route. In an eighth example of the method, optionally including one or more or each of the first through seventh examples, the completion rate describes a percentage that the virtual vehicle, and thus the real vehicle, successfully finishes the route based on a battery voltage or state of charge (SOC) and the confidence threshold is a pre-determined value for the completion rate.

The disclosure also provides support for a physics-based simulation system, comprising: one or more processors, and memory storing instructions executable by the one or more processors to: enter a route via a fleet management system (FMS) communicatively coupled to the physics-based simulation system, validate the route via the physics-based simulation system, the physics-based simulation system comprising a vehicle model that simulates operation of a virtual vehicle and a segmentation model, store collected simulation data in a data lake, and generate a statistical summary report based on simulation data stored in the data lake and display the statistical summary report to a user. In a first example of the system, validating the route via the physics-based simulation system comprises, determining one or more potential routes with Azure Maps and receiving route data for the one or more potential routes, the route data including coordinates of an initial location, a final destination, and each stop prior to reaching the final destination, and mapping coordinates in Azure Maps to coordinates in OpenStreetMap for each potential route by identifying data elements in OpenStreetMap that include the coordinates, the data elements being nodes, ways, or relations.

In a second example of the system, optionally including the first example, each element has route parameters associated with the element and the segmentation model is a classification model that generates a plurality of segments by grouping coordinates that define a potential route based on the coordinates having uniform or nearly uniform route parameters. In a third example of the system, optionally including one or both of the first and second examples, each segment is serially entered into the vehicle model in a pre-determined order and the vehicle model comprises a plurality of vehicle subsystem models that are trained to receive relevant route parameters from each segment in addition to sensor data. In a fourth example of the system, optionally including one or more or each of the first through third examples, the pre-determined order is based on an order wherein the virtual vehicle travels along the potential route chronologically. In a fifth example of the system, optionally including one or more or each of the first through fourth examples, output generated by the vehicle model is entered as input into the vehicle model for a subsequent segment of the plurality of segments.

The disclosure also provides support for a method, comprising: obtaining input parameter entered as input into a fleet management system (FMS), obtaining route data for one or more potential routes with azure Maps, obtaining route parameters for one or more potential routes with OpenStreetMap, entering route data and route parameters as input to a segmentation model to obtain a plurality of segments with segmented route parameters, obtaining topographical and geographical location data from online databases, entering route parameters and route parameters as input to a vehicle model to predict battery voltage, and sending simulation data to a data lake for storage. In a first example of the method, training of the segmentation model comprises entering a potential training route and a plurality of route training parameters as input to an initial segmentation model and comparing a plurality of training segments of a training potential route with a ground truth plurality of training segments to calculate a loss function, the ground truth plurality of training segments being pre-determined and annotated.

In a second example of the method, optionally including the first example, the ground truth plurality of training segments is annotated with all coordinates in each training segment or an initial coordinate and a final coordinate that make up each training segment. In a third example of the method, optionally including one or both of the first and second examples, training of the vehicle model comprises entering a plurality of training segments, their respective route training parameters, and vehicle operation training data as input to an initial vehicle model and comparing ground truth vehicle subsystem training parameters with generated vehicle subsystem training parameters output from the initial vehicle model to calculate a loss function that is used to adjust model parameters of the initial vehicle model. In a fourth example of the method, optionally including one or more or each of the first through third examples, the vehicle operation training data is vehicle operation training data of a plurality of vehicle subsystems obtained from vehicle sensors while driving on each training segment.

While various embodiments have been described above, it should be understood that they have been presented by way of example, and not limitation. It will be apparent to persons skilled in the relevant arts that the disclosed subject matter may be embodied in other specific forms without departing from the spirit of the subject matter. The embodiments described above are therefore to be considered in all respects as illustrative, not restrictive.

Note that the example control and estimation routines included herein can be used with various powertrain and/or vehicle system configurations. The control methods and routines disclosed herein may be stored as executable instructions in non-transitory memory and may be carried out by the control system including the controller in combination with the various sensors, actuators, and other transmission and/or vehicle hardware. Further, portions of the methods may be physical actions taken in the real world to change a state of a device. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example examples described herein, but is provided for case of illustration and description. One or more of the illustrated actions, operations and/or functions may be repeatedly performed depending on the particular strategy being used. Further, the described actions, operations and/or functions may graphically represent code to be programmed into non-transitory memory of the computer readable storage medium in the vehicle and/or transmission control system, where the described actions are carried out by executing the instructions in a system including the various hardware components in combination with the electronic controller. One or more of the method steps described herein may be omitted if desired.

It will be appreciated that the configurations and routines disclosed herein are exemplary in nature, and that these specific examples are not to be considered in a limiting sense, because numerous variations are possible. For example, the above technology can be applied to powertrains that include different types of propulsion sources including different types of electric machines, internal combustion engines, and/or transmissions. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure. As used herein, the terms “approximately” and “substantially” are construed to mean plus or minus five percent of the range, unless otherwise specified.

1. A method for operating a fleet of vehicles having a central recharging location, comprising:
operating at least a first vehicle of the fleet and a second vehicle of the fleet with different physical characteristics in response to a completion rate being greater than a confidence threshold, where each of the first vehicle and the second vehicle only externally recharge at the central recharging location without external recharging occurring on a respective route of each of the first vehicle and the second vehicle and where the completion rate is generated by:
for each of the first vehicle and the second vehicle, entering the respective route of a plurality of routes via a fleet management system (FMS) communicatively coupled to a physics-based simulation system;
validating each route via the physics-based simulation system, the physics-based simulation system comprising a vehicle model that simulates operation of a virtual vehicle and a segmentation model;
storing collected simulation data in a data lake; and
generating a statistical summary report based on simulation data stored in the data lake and displaying the statistical summary report to a user;
in response to the completion rate being greater than the confidence threshold, selecting one of the first vehicle and the second vehicle to send on one route of the plurality of routes based on a highest completion rate and sending an unselected vehicle on another route of the plurality of routes based on a next highest completion rate; and
in response to a route not being matched to either of the first vehicle and the second vehicle due to the completion rate not being greater than the confidence threshold, sending a hybrid vehicle or internal combustion engine (ICE) vehicle on the route.

2. The method of claim 1, wherein each route comprises an initial location, a final destination, a number of anticipated stops, and selectable input parameters and each of the initial location, the final destination, and the number of anticipated stops are entered as physical addresses to the FMS.

3. The method of claim 2, wherein the initial location and the final destination are the same and have a same physical address, a central recharging location is located at the initial location, and the selectable input parameters are desired route parameters.

4. The method of claim 3, wherein route parameters include speed, road grade, wind conditions, traffic conditions, weather conditions, sinuosity, and other route parameters that affect operation of a real vehicle.

5. The method of claim 1, wherein validating the route via the physics-based simulation system comprising the vehicle model that simulates operation of the virtual vehicle comprises:
transmitting the route to Azure Maps to determine one or more potential routes;
receiving route parameters from OpenStreetMap based on route data obtained from Azure Maps;
segmenting the route based on uniformity of route parameters to generate a plurality of segments;
receiving topographic data, geographic location data, and other route parameters from online databases; and
simulating operation of the virtual vehicle by entering route parameters of the plurality of segments as input to the vehicle model.

6. The method of claim 5, wherein segmenting the route based on uniformity of route parameters to generate the plurality of segments is performed with the segmentation model for each of the one or more potential routes and both of the segmentation model and the vehicle model are machine learning (ML) models.

7. The method of claim 5, wherein the route parameters entered as input to the vehicle model include the selectable input parameters received as user input, randomized input parameters, or input parameters based on real-time conditions, near real-time conditions, and historical conditions of the route.

8. The method of claim 1, wherein the statistical summary report includes the completion rate, a confidence interval for the completion rate, a summary of expected weather conditions, traffic conditions, and wind conditions, and the like on segmented portions of the route and/or an entire route.

9. The method of claim 8, wherein the completion rate describes a percentage that the virtual vehicle, and thus the real vehicle, successfully finishes the route based on a battery voltage or state of charge (SOC) and the confidence threshold is a pre-determined value for the completion rate.

10. A physics-based simulation system, comprising:
one or more processors; and
memory storing instructions executable by the one or more processors to:
enter a route via a fleet management system (FMS) communicatively coupled to the physics-based simulation system;
validate the route via the physics-based simulation system, the physics-based simulation system comprising a vehicle model that simulates operation of a virtual vehicle and a segmentation model;
store collected simulation data in a data lake; and
generate a statistical summary report based on simulation data stored in the data lake and display the statistical summary report to a user.

11. The system of claim 10, wherein validating the route via the physics-based simulation system comprises;
determining one or more potential routes with Azure Maps and receiving route data for the one or more potential routes, the route data including coordinates of an initial location, a final destination, and each stop prior to reaching the final destination; and
mapping coordinates in Azure Maps to coordinates in OpenStreetMap for each potential route by identifying data elements in OpenStreetMap that include the coordinates, the data elements being nodes, ways, or relations.

12. The system of claim 11, wherein each element has route parameters associated with the element and the segmentation model is a classification model that generates a plurality of segments by grouping coordinates that define a potential route based on the coordinates having uniform or nearly uniform route parameters.

13. The system of claim 12, wherein each segment is serially entered into the vehicle model in a pre-determined order and the vehicle model comprises a plurality of vehicle subsystem models that are trained to receive relevant route parameters from each segment in addition to sensor data.

14. The system of claim 13, wherein the pre-determined order is based on an order wherein the virtual vehicle travels along the potential route chronologically.

15. The system of claim 12, wherein output generated by the vehicle model is entered as input into the vehicle model for a subsequent segment of the plurality of segments.

16. A method, comprising:
obtaining input parameter entered as input into a fleet management system (FMS);
obtaining route data for one or more potential routes with Azure Maps;
obtaining route parameters for one or more potential routes with OpenStreetMap;
entering route data and route parameters as input to a segmentation model to obtain a plurality of segments with segmented route parameters;
obtaining topographical and geographical location data from online databases;
entering route parameters and route parameters as input to a vehicle model to predict battery voltage; and
sending simulation data to a data lake for storage.

17. The method of claim 16, wherein training of the segmentation model comprises entering a potential training route and a plurality of route training parameters as input to an initial segmentation model and comparing a plurality of training segments of a training potential route with a ground truth plurality of training segments to calculate a loss function, the ground truth plurality of training segments being pre-determined and annotated.

18. The method of claim 17, wherein the ground truth plurality of training segments is annotated with all coordinates in each training segment or an initial coordinate and a final coordinate that make up each training segment.

19. The method of claim 16, wherein training of the vehicle model comprises entering a plurality of training segments, their respective route training parameters, and vehicle operation training data as input to an initial vehicle model and comparing ground truth vehicle subsystem training parameters with generated vehicle subsystem training parameters output from the initial vehicle model to calculate a loss function that is used to adjust model parameters of the initial vehicle model.

20. The method of claim 19, wherein the vehicle operation training data is vehicle operation training data of a plurality of vehicle subsystems obtained from vehicle sensors while driving on each training segment.
